(19) United States
(12) Patent Application Publication
(10) Pub. No.: US 2026/0204334 A1
(43) Pub. Date: Jul. 16, 2026

(54) SEMICONDUCTOR MEMORY DEVICE AND MEMORY SYSTEM

(71) Applicant: Kioxia Corporation, Minato-ku (JP)

(72) Inventors: Yasuhiro HIRASHIMA, Kawasaki Kanagawa (JP); Shigeki NAGASAKA, Kawasaki Kanagawa (JP); Toshiyuki KOUCHI, Kawasaki Kanagawa (JP); Daisuke ARIZONO, Yokohama Kanagawa (JP); Tomonori KUROSAWA, Zama Kanagawa (JP); Mitsuhiro ABE, Kawasaki Kanagawa (JP)

(73) Assignee: Kioxia Corporation, Minato-ku (JP)

(21) Appl. No.: 19/322,740

(22) Filed: Sep. 9, 2025

(30) Foreign Application Priority Data
Jan. 16, 2025 (JP) 2025-006000

(51) Int. Cl. G11C 29/12

(52) U.S. Cl. CPC G11C 29/12005

(57) ABSTRACT

A semiconductor memory device includes a memory cell array, a first pad electrode that receives write data and outputs read data, a comparator having one input terminal connected to the first pad electrode and the other input terminal to which a reference voltage is applied, a latch circuit that latches an output signal of the comparator corresponding to a latch enable signal, and a second pad electrode to which the latch enable signal is supplied at the input of the write data. This semiconductor memory device receives a plurality of bits of test data input via the first pad electrode, and generates data indicating whether or not a bit error has occurred at the input of the test data in the write data training operation. This semiconductor memory device is configured to be able to output the data indicating whether or not the bit error has occurred.

### CROSS-REFERENCE TO RELATED APPLICATIONS

This application is based upon and claims the benefit of Japanese Patent Application No. 2025-006000, filed on Jan. 16, 2025, the entire contents of which are incorporated herein by reference.

### BACKGROUND

### Field

Embodiments described herein relate generally to a semiconductor memory device and a memory system.

### Description of the Related Art

There has been known a memory system that includes a plurality of semiconductor memory devices and a controller. The semiconductor memory device includes a memory cell array.

### BRIEF DESCRIPTION OF THE DRAWINGS

FIG. 1 is a schematic block diagram illustrating a configuration of a memory system 10 according to a first embodiment;

FIG. 2 is a schematic side view illustrating an exemplary configuration of the memory system 10;

FIG. 3 is a schematic plan view illustrating the exemplary configuration;

FIG. 4 is a schematic block diagram illustrating a configuration of a memory die MD according to the first embodiment;

FIG. 5 is a schematic circuit diagram illustrating a configuration of a part of the memory die MD;

FIG. 6 is a schematic perspective view illustrating a configuration of a part of the memory die MD;

FIG. 7 is a schematic circuit diagram illustrating a configuration of a part of the memory die MD;

FIG. 8 is a schematic circuit diagram illustrating a configuration of a part of the memory die MD;

FIG. 9 is a schematic timing chart illustrating a state of a write data training operation according to the first embodiment;

FIG. 10 is a schematic timing chart illustrating a state of the write data training operation according to a comparative example;

FIG. 11 is a schematic circuit diagram illustrating an exemplary configuration of an input/output control circuit I/O according to the first embodiment;

FIG. 12 is a schematic circuit diagram illustrating an exemplary configuration of a pointer generation circuit 250 according to the first embodiment;

FIG. 13 is a schematic waveform diagram illustrating an input/output signal of the pointer generation circuit 250 according to the first embodiment;

FIG. 14 is a schematic circuit diagram illustrating an exemplary configuration of a parallel conversion circuit 260 according to the first embodiment;

FIG. 15A is a schematic circuit diagram illustrating an exemplary configuration of a data storage region 270 according to the first embodiment;

FIG. 15B is a schematic circuit diagram illustrating an exemplary configuration of the data storage region 270 according to the first embodiment;

FIG. 16 is a schematic timing chart illustrating a state of the write data training operation according to the first embodiment;

FIG. 17 is a drawing illustrating an exemplary result of a comparison performed in the data storage region 270 according to the first embodiment;

FIG. 18 is a drawing illustrating an exemplary result of a comparison performed in the data storage region 270 according to the first embodiment;

FIG. 19 is a schematic timing chart illustrating an exemplary expected value input method according to the first embodiment;

FIG. 20 is a schematic circuit diagram illustrating an exemplary configuration of the input/output control circuit I/O;

FIG. 21 is a schematic circuit diagram illustrating an exemplary configuration of the input/output control circuit I/O;

FIG. 22 is a schematic circuit diagram illustrating an exemplary configuration of the input/output control circuit I/O;

FIG. 23 is a schematic timing chart in a case where the write data training operation according to the first embodiment is applied to SCA;

FIG. 24 is a schematic timing chart in a case where the write data training operation is simultaneously executed on a plurality of memory dies MD;

FIG. 25 is a schematic circuit diagram illustrating a configuration of a part of an input/output control circuit I/O according to a second embodiment;

FIG. 26 is a schematic circuit diagram illustrating a configuration of an expected value generator/comparator 280 according to the second embodiment;

FIG. 27 is a flowchart illustrating an exemplary write data training operation of the input/output control circuit I/O according to the second embodiment;

FIG. 28 is a schematic timing chart illustrating a part of the write data training operation of the input/output control circuit I/O according to the second embodiment;

FIG. 29 is a schematic circuit diagram illustrating a configuration of a part of an input/output control circuit I/O according to a third embodiment;

FIG. 30 is a schematic circuit diagram illustrating a configuration of an expected value generator/comparator 280b according to the third embodiment;

FIG. 31 is a drawing for describing a write data training operation according to a fourth embodiment;

FIG. 32 is a drawing for describing the write data training operation according to a fourth embodiment;

FIG. 33 is a schematic circuit diagram illustrating a configuration of a part of an input/output control circuit I/O according to the fourth embodiment;

FIG. 34 is a schematic circuit diagram illustrating a configuration of an error determination circuit 290 according to the fourth embodiment; and

FIG. 35 is a schematic timing chart illustrating a state of a write data training operation according to a fifth embodiment.

### DETAILED DESCRIPTION

A semiconductor memory device according to one embodiment comprises: a memory cell array; a first pad electrode that receives write data at an input of the write data to be written in the memory cell array and outputs read data at an output of the read data read from the memory cell array; a first comparator having one input terminal connected to the first pad electrode and the other input terminal to which a reference voltage is applied; a first latch circuit that latches an output signal of the first comparator corresponding to a first latch enable signal; and a second pad electrode to which the first latch enable signal is supplied at the input of the write data. The semiconductor memory device is configured to be able to perform a write data training operation at an adjustment of a time interval between a timing of inputting the write data to the first pad electrode and a timing of inputting the first latch enable signal to the second pad electrode, and at an adjustment of the reference voltage. The semiconductor memory device receives a plurality of bits of test data via the first pad electrode, and generates data indicating whether or not a bit error has occurred at the input of the test data in the write data training operation. The semiconductor memory device is configured to be able to output the data indicating whether or not the bit error has occurred.

Next, the semiconductor memory devices according to embodiments are described in detail with reference to the drawings. The following embodiments are only examples, and not described for the purpose of limiting the present invention. For convenience of description, a part of a configuration and the like is sometimes omitted. Parts common in a plurality of embodiments are attached by same reference numerals and their descriptions may be omitted.

In this specification, when referring to a “semiconductor memory device”, it may mean a memory die and may mean a memory system including a controller die, such as a memory chip, a memory card, and a Solid State Drive (SSD). Further, it may mean a configuration including a host computer, such as a smartphone, a tablet terminal, and a personal computer.

In this specification, when it is referred that a first configuration “is electrically connected” to a second configuration, the first configuration may be directly connected to the second configuration, and the first configuration may be connected to the second configuration via a wiring, a semiconductor member, a transistor, or the like. For example, when three transistors are connected in series, even when the second transistor is in an OFF state, the first transistor is “electrically connected” to the third transistor.

In this specification, when it is referred that the first configuration “is connected between” the second configuration and a third configuration, it may mean that the first configuration, the second configuration, and the third configuration are connected in series and the second configuration is connected to the third configuration via the first configuration.

In this specification, a direction parallel to an upper surface of the substrate is referred to as an X-direction, a direction parallel to the upper surface of the substrate and perpendicular to the X-direction is referred to as a Y-direction, and a direction perpendicular to the upper surface of the substrate is referred to as a Z-direction.

In this specification, when referring to a “width”, a “length”, a “thickness”, or the like of a configuration, a member, or the like in a predetermined direction, this may mean a width, a length, a thickness, or the like in a cross-sectional surface or the like observed with a Scanning electron microscopy (SEM), a Transmission electron microscopy (TEM), or the like.

### First Embodiment

### Memory System 10

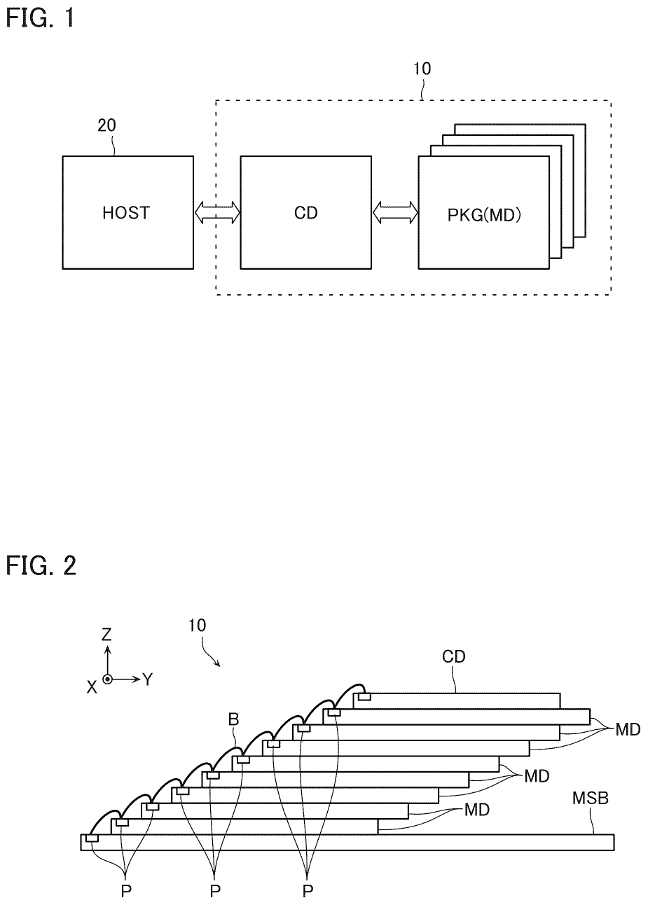

FIG. 1 is a schematic block diagram illustrating a configuration of a memory system 10 according to the embodiment.

The memory system 10, for example, reads, writes, and erases user data according to a signal transmitted from a host computer 20. The memory system 10 is, for example, a memory card, an SSD, or another system that can store user data. The memory system 10 includes a plurality of packages PKG and a controller die CD connected to these plurality of packages PKG and the host computer 20. Each of the packages PKG includes a plurality of memory dies MD. Each of the memory dies MD can store the user data. The controller die CD includes, for example, a processor, a RAM, and the like, and performs conversion between a logical address and a physical address, bit error detection/correction, a garbage collection (compaction), a wear leveling, and the like.

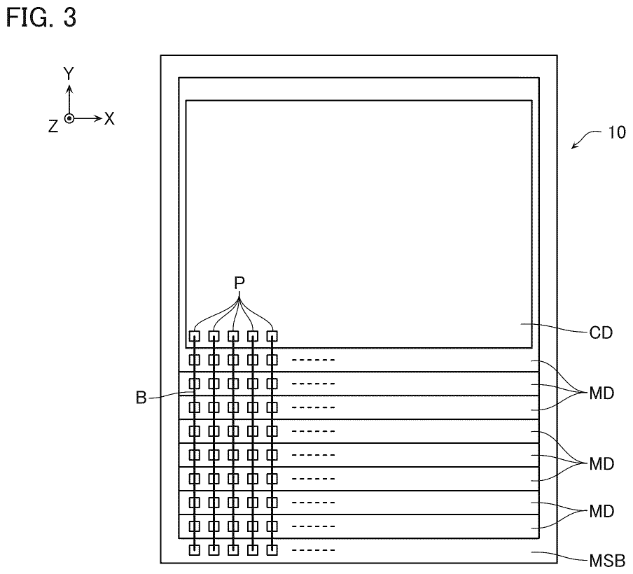

FIG. 2 is a schematic side view illustrating an exemplary configuration of the memory system 10 according to the embodiment. FIG. 3 is a schematic plan view illustrating the exemplary configuration. For convenience of explanation, a part of the configuration is omitted in FIG. 2 and FIG. 3.

As illustrated in FIG. 2, the memory system 10 according to the embodiment includes a mounting substrate MSB, the plurality of memory dies MD stacked on the mounting substrate MSB, and the controller die CD stacked on the memory dies MD. A pad electrode P is disposed in a region at an end portion in the Y-direction of an upper surface of the mounting substrate MSB, and a part of another region is bonded to a lower surface of the memory die MD via an adhesive and the like. A pad electrode P is disposed in a region at an end portion in the Y-direction of an upper surface of the memory die MD, and another region is bonded to a lower surface of another memory die MD or the controller die CD via the adhesive and the like. A pad electrode P is disposed in a region at an end portion in the Y-direction of an upper surface of the controller die CD.

As illustrated in FIG. 3, each of the mounting substrate MSB, the plurality of memory dies MD, and the controller die CD includes a plurality of pad electrodes P arranged in the X-direction. The plurality of pad electrodes P disposed on the mounting substrate MSB, the plurality of memory dies MD, and the controller die CD are mutually connected via bonding wires B.

The configuration illustrated in FIG. 2 and FIG. 3 is only an example, and the specific configuration can be adjusted as appropriate. For example, in the example illustrated in FIG. 2 and FIG. 3, the controller die CD is stacked on the plurality of memory dies MD, and these configurations are connected by the bonding wires B. In this configuration, the plurality of memory dies MD and the controller die CD are included in one package. However, the controller die CD may be included in a different package from the memory die MD. The plurality of memory dies MD and the controller die CD may be mutually connected via a through electrode or the like instead of the bonding wire B.

### Configuration of Memory Die MD

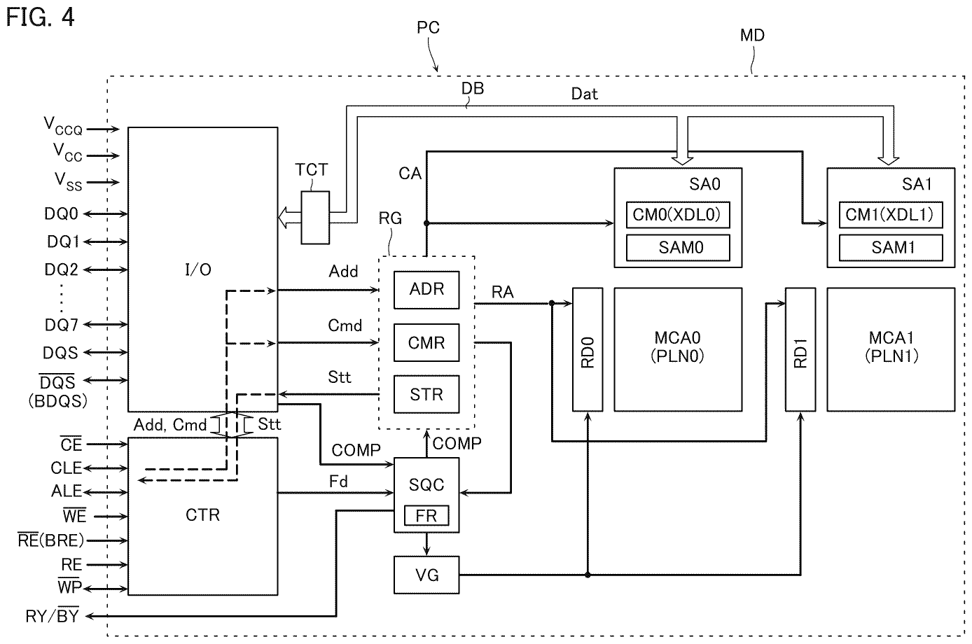

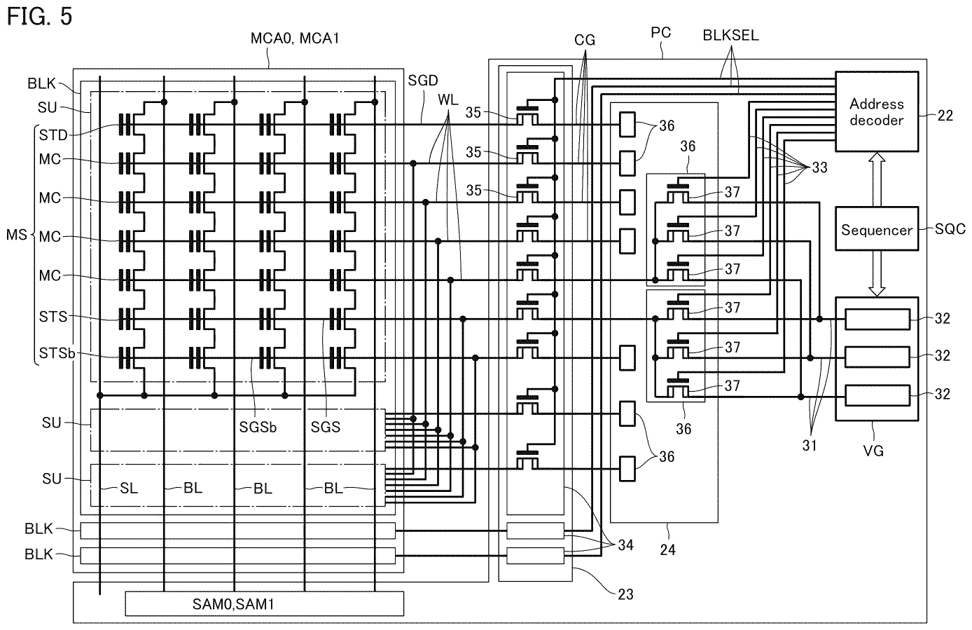

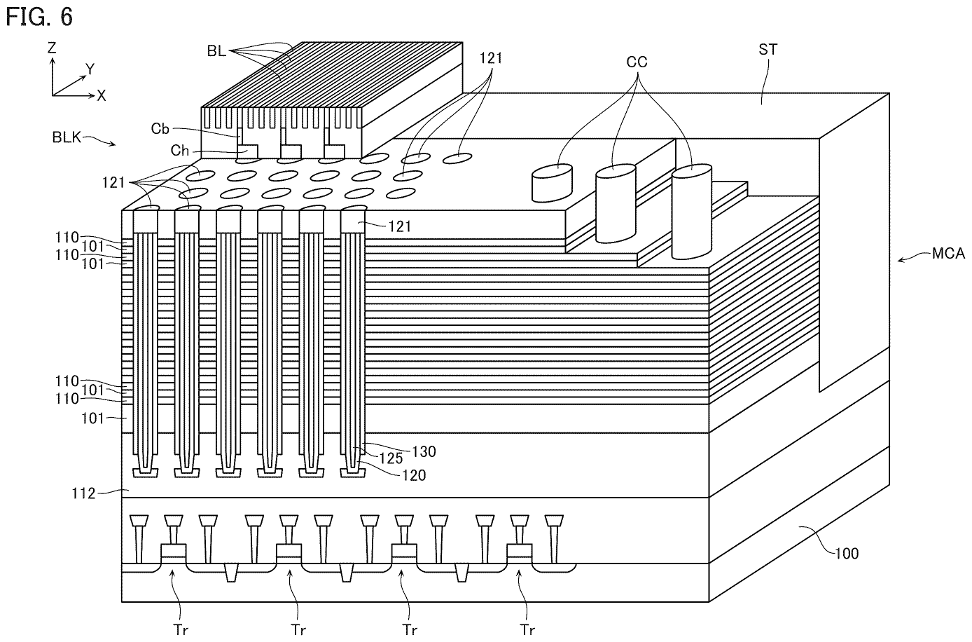

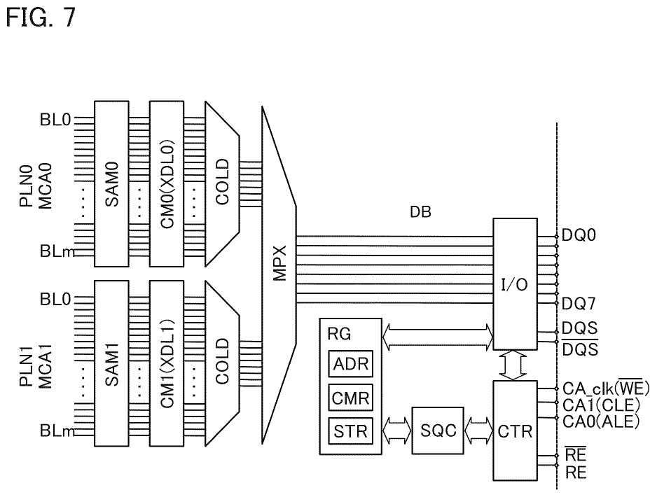

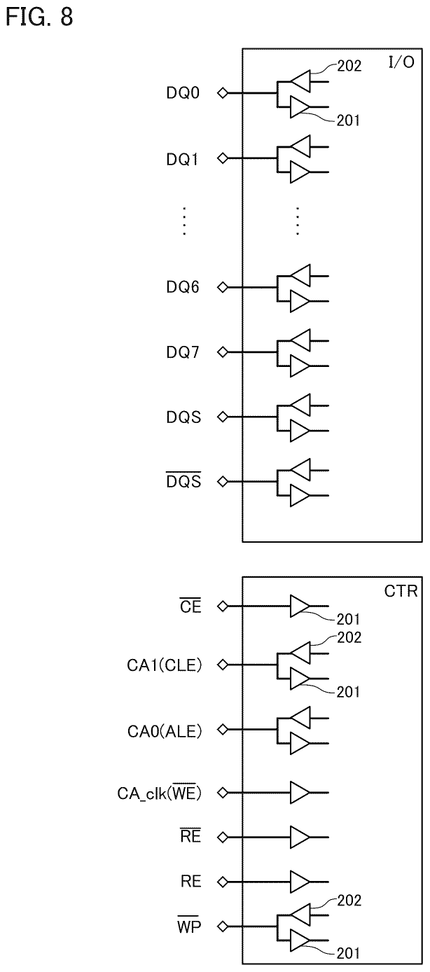

FIG. 4 is a schematic block diagram illustrating a configuration of the memory die MD according to the embodiment. FIG. 5 is a schematic circuit diagram illustrating a configuration of a part of the memory die MD. FIG. 6 is a schematic perspective view illustrating the configuration of a part of the memory die MD. FIG. 7 and FIG. 8 are schematic circuit diagrams illustrating the configuration of a part of the memory die MD. For convenience of explanation, a part of the configuration is omitted in FIG. 4 to FIG. 8.

FIG. 4 illustrates a plurality of control terminals and the like. These plurality of control terminals are represented as control terminals corresponding to a high active signal (positive logic signal) in some cases, represented as control terminals corresponding to a low active signal (negative logic signal) in some cases, and represented as control terminals corresponding to both the high active signal and the low active signal in some cases. In FIG. 4, a reference sign of the control terminal corresponding to the low active signal includes an overline (overbar). In this specification, a reference sign of the control terminal corresponding to the low active signal includes a slash (“/”). The description of FIG. 4 is an example, and specific aspects are appropriately adjustable. For example, a part of or all of the high active signals can be changed to the low active signals, or a part of or all of the low active signals can be changed to the high active signals. Instead of the overline (overbar) and the slash (“/”), B can be attached to a capital letter.

At sides of the plurality of control terminals illustrated in FIG. 4, arrows indicating input/output directions are illustrated. In FIG. 4, the control terminals with left-right arrows can be used for inputting data or other signals from the controller die CD to the memory die MD. In FIG. 4, the control terminals with right-left arrows can be used for outputting data or other signals from the memory die MD to the controller die CD. In FIG. 4, the control terminals with left-right double arrows can be used for both of inputting data or other signals from the controller die CD to the memory die MD and outputting data or other signals from the memory die MD to the controller die CD.

As illustrated in FIG. 4, the memory die MD includes memory cell arrays MCA0, MCA1 storing user data, and a peripheral circuit PC connected to the memory cell arrays MCA0, MCA1. In the following description, the memory cell arrays MCA0, MCA1 are referred to as a memory cell array MCA in some cases. The memory cell arrays MCA0, MCA1 are referred to as planes PLN0, PLN1 in some cases.

### Configuration of Memory Cell Array MCA

As illustrated in FIG. 5, the memory cell array MCA includes a plurality of memory blocks BLK. These plurality of memory blocks BLK each include a plurality of string units SU. These plurality of string units SU each include a plurality of memory strings MS. These plurality of memory strings MS have one ends each connected to the peripheral circuit PC via bit lines BL. Furthermore, these plurality of memory strings MS have the other ends each connected to the peripheral circuit PC via a common source line SL.

The memory string MS includes a drain-side select transistor STD, a plurality of memory cells MC (memory cell transistors), a source-side select transistor STS, and a source-side select transistor STSb, which are connected in series between the bit line BL and the source line SL. Hereinafter, the drain-side select transistor STD, the source-side select transistor STS, and the source-side select transistor STSb may be simply referred to as select transistors (STD, STS, STSb).

The memory cell MC is a field-effect type transistor including a semiconductor layer, a gate insulating film, and a gate electrode. The semiconductor layer functions as a channel region. The gate insulating film includes an electric charge accumulating film. The memory cell MC has a threshold voltage that changes according to an electric charge amount in the electric charge accumulating film. The memory cell MC stores one bit or a plurality of bits of user data. Word lines WL are connected to the respective gate electrodes of the plurality of memory cells MC corresponding to one memory string MS. These respective word lines WL are connected to all of the memory strings MS in one memory block BLK in common.

The select transistors (STD, STS, STSb) are field-effect type transistors including a semiconductor layer, a gate insulating film, and a gate electrode. The semiconductor layer functions as a channel region. Select gate lines (SGD, SGS, SGSb) are connected to the gate electrodes of the select transistors (STD, STS, STSb), respectively. The drain-side select gate line SGD is disposed corresponding to the string unit SU and connected to all of the memory strings MS in one string unit SU in common. The source-side select gate line SGS is connected to all of the memory strings MS in the memory block BLK in common. The source-side select gate line SGSb is connected to all of the memory strings MS in the memory block BLK in common.

For example, as illustrated in FIG. 6, the memory cell array MCA is disposed above a semiconductor substrate 100. In the example in FIG. 6, between the semiconductor substrate 100 and the memory cell array MCA, a plurality of transistors Tr constituting the peripheral circuit PC are disposed.

The memory cell array MCA includes a plurality of memory blocks BLK arranged in the Y-direction. Between two memory blocks BLK adjacent to one another in the Y-direction, an inter-block insulating layer ST of silicon oxide (SiO₂) or the like is disposed.

For example, as illustrated in FIG. 6, the memory block BLK includes a plurality of conductive layers 110 arranged in the Z-direction, a plurality of semiconductor columns 120 extending in the Z-direction, and a respective plurality of gate insulating films 130 disposed between the plurality of conductive layers 110 and the plurality of semiconductor columns 120.

The conductive layer 110 is an approximately plate-shaped conductive layer extending in the X-direction. The conductive layer 110 may include a stacked film of a barrier conductive film of titanium nitride (TiN) or the like, and a metal film of tungsten (W) or the like, or the like. For example, the conductive layer 110 may contain polycrystalline silicon containing impurities, such as phosphorus (P) or boron (B), or the like. Insulating layers 101 of silicon oxide (SiO₂) or the like are disposed between the plurality of conductive layers 110 arranged in the Z-direction.

Among the plurality of conductive layers 110, two or more conductive layers 110 positioned at the lowermost layer function as the source-side select gate line SGS, SGSb (FIG. 5) and gate electrodes of the plurality of source-side select transistors STS, STSb connected to the source-side select gate line SGS, SGSb. These plurality of conductive layers 110 are electrically independent in every memory block BLK.

A plurality of conductive layers 110 positioned above these conductive layers 110 function as the word lines WL (FIG. 5) and gate electrodes of the plurality of memory cells MC (FIG. 5) connected to the word lines WL. These plurality of conductive layers 110 are each electrically independent in every memory block BLK.

One or a plurality of conductive layers 110 positioned above these conductive layers 110 function as the drain-side select gate line SGD and gate electrodes of the plurality of drain-side select transistors STD (FIG. 5) connected to the drain-side select gate line SGD. These plurality of conductive layers 110 have widths in the Y-direction smaller than those of the other conductive layers 110.

A semiconductor layer 112 is disposed below the conductive layer 110. The semiconductor layer 112 may contain, for example, polycrystalline silicon containing impurities such as phosphorus (P) or boron (B), or the like. Between the semiconductor layer 112 and the conductive layer 110, an insulating layer 101 of silicon oxide (SiO₂) or the like is disposed.

The semiconductor layer 112 functions as the source line SL (FIG. 5). The source line SL is disposed in common, for example, for all the memory blocks BLK included in the memory cell array MCA.

For example, as illustrated in FIG. 6, the semiconductor columns 120 are arranged in the X-direction and the Y-direction in a predetermined pattern. The semiconductor columns 120 function as the channel regions of the plurality of memory cells MC and the select transistors (STD, STS, STSb) included in one memory string MS (FIG. 5). The semiconductor column 120 is, for example, a semiconductor layer of polycrystalline silicon (Si) or the like. For example, as illustrated in FIG. 6, the semiconductor column 120 has an approximately closed-bottomed cylindrical shape and includes an insulating layer 125 of silicon oxide or the like, in a center part. The semiconductor column 120 has an outer peripheral surface that is surrounded by each of the conductive layers 110 and is faced to the conductive layers 110.

In the upper end portion of the semiconductor column 120, an impurity region 121 containing N-type impurities, such as phosphorus (P), is disposed. The impurity region 121 is connected to the bit line BL via a contact Ch and a contact Cb.

The gate insulating film 130 has an approximately closed-bottomed cylindrical shape that covers the outer peripheral surface of the semiconductor column 120. The gate insulating film 130 includes, for example, a tunnel insulating film, an electric charge accumulating film, and a block insulating film, which are stacked between the semiconductor column 120 and the conductive layers 110. The tunnel insulating film and the block insulating film are, for example, insulating films of silicon oxide (SiO₂) or the like. The electric charge accumulating film is, for example, a film that can accumulate the electric charges of silicon nitride (Si₃N₄) or the like. The tunnel insulating film, the electric charge accumulating film, and the block insulating film have approximately cylindrical shapes and extend in the Z-direction along the outer peripheral surface of the semiconductor column 120 excluding the contact portion between the semiconductor column 120 and the semiconductor layer 112.

The gate insulating film 130 may, for example, include a floating gate of polycrystalline silicon including N-type or P-type impurities, or the like.

The plurality of conductive layers 110 have end portions in the X-direction where a plurality of contacts CC are disposed. The plurality of conductive layers 110 are connected to the peripheral circuit PC via these plurality of contacts CC. As illustrated in FIG. 6, these plurality of contacts CC extend in the Z-direction, and have lower ends connected to the conductive layers 110. The contacts CC may, for example, include a stacked film of a barrier conductive film of titanium nitride (TiN) or the like and a metal film of tungsten (W) or the like, or the like.

### Configuration of Peripheral Circuit PC

For example, as illustrated in FIG. 4, the peripheral circuit PC includes row decoders RD0, RD1 and sense amplifiers SA0, SA1, which are connected to the memory cell arrays MCA0, MCA1, respectively. The peripheral circuit PC includes a voltage generation circuit VG and a sequencer SQC. The peripheral circuit PC includes an input/output control circuit I/O (first circuit), a logic circuit CTR, a register RG, and a data output timing adjustment circuit TCT. The register RG includes an address register ADR, a command register CMR, and a status register STR. In the following description, the row decoders RD0, RD1 are referred to as a row decoder RD, and the sense amplifiers SA0, SA1 are referred to as a sense amplifier SA, in some cases.

### Configuration of Row Decoder RD

For example, as illustrated in FIG. 5, the row decoder RD (FIG. 4) includes an address decoder 22 decoding address data Add (FIG. 4), and a block select circuit 23 and a voltage select circuit 24 that transfer an operating voltage to the memory cell array MCA in response to an output signal from the address decoder 22.

The address decoder 22 includes, for example, as illustrated in FIG. 5, a plurality of block select lines BLKSEL and a plurality of voltage select lines 33. For example, the address decoder 22 sequentially refers to a row address RA in the address register ADR (FIG. 4) in response to the control signal from the sequencer SQC, decodes this row address RA to cause a predetermined block select transistor 35 and a predetermined voltage select transistor 37 corresponding to the row address RA to be in an ON state, and cause the block select transistors 35 and the voltage select transistors 37 other than those to be in an OFF state. For example, voltages of the predetermined block select line BLKSEL and voltage select line 33 are set to be in an “H” state and voltages other than those are set to be in an “L” state. When a P-channel type transistor is used, not an N-channel type transistor, an inverse voltage is applied to these wirings.

In the illustrated example, in the address decoder 22, one block select line BLKSEL is disposed per memory block BLK. However, this configuration is appropriately changeable. For example, one block select line BLKSEL may be included in per two or more memory blocks BLK.

The block select circuit 23 includes, for example, as illustrated in FIG. 5, a plurality of block selectors 34 corresponding to the memory blocks BLK. These plurality of block selectors 34 each include a plurality of the block select transistors 35 corresponding to the word lines WL and the select gate lines (SGD, SGS, SGSb). The block select transistor 35 is, for example, a field-effect type high breakdown voltage transistor. The block select transistors 35 have drain electrodes each electrically connected to the corresponding word lines WL or select gate lines (SGD, SGS, SGSb). Source electrodes are each electrically connected to a voltage supply line 31 via a wiring CG and the voltage select circuit 24. Gate electrodes are connected to the corresponding block select line BLKSEL in common.

Note that the block select circuit 23 further includes a plurality of transistors (not illustrated in FIG. 5). These plurality of transistors are field-effect type high breakdown voltage transistors connected between the select gate lines (SGD, SGS, SGSb) and voltage supply lines to which a ground voltage V_{SS} is applied. These plurality of transistors apply the select gate lines (SGD, SGS, SGSb) included in unselected memory blocks BLK with the ground voltage V_{SS}. Note that the plurality of word lines WL included in the unselected memory blocks BLK enter a floating state.

The voltage select circuit 24 includes, for example, as illustrated in FIG. 5, a plurality of voltage selectors 36 corresponding to the word lines WL and the select gate lines (SGD, SGS, SGSb). These plurality of voltage selectors 36 each include a plurality of the voltage select transistors 37. The voltage select transistor 37 is, for example, a field-effect type high breakdown voltage transistor. The voltage select transistors 37 have drain terminals each electrically connected to the corresponding word line WL or select gate line (SGD, SGS, SGSb) via the wiring CG and the block select circuit 23. Source terminals are each electrically connected to the corresponding voltage supply line 31. Gate electrodes are each connected to the corresponding voltage select line 33.

### Configuration of Sense Amplifier SA

The sense amplifiers SA0, SA1 (FIG. 4) include sense amplifier modules SAM0, SAM1 and cache memories CM0, CM1, respectively. The cache memories CM0, CM1 include latch circuits XDL0, XDL1, respectively.

Note that, in the following description, the sense amplifier modules SAM0, SAM1 may be referred to as sense amplifier modules SAM, the cache memories CM0, CM1 may be referred to as cache memories CM, and the latch circuits XDL0, XDL1 may be referred to as latch circuits XDL.

The sense amplifier module SAM includes, for example, respective sense circuits corresponding to a plurality of bit lines BL, a plurality of latch circuits connected to the sense circuits, and the like.

The cache memory CM includes a plurality of latch circuits XDL. The plurality of latch circuits XDL are connected to the respective latch circuits in the sense amplifier module SAM. In the latch circuit XDL, for example, user data Dat to be written in the memory cell MC or user data Dat read from the memory cell MC is stored.

For example, as illustrated in FIG. 7, a column decoder COLD is connected to the cache memory CM. The column decoder COLD decodes a column address CA stored in the address register ADR (FIG. 4) to select the latch circuit XDL corresponding to the column address CA.

The user data Dat included in these plurality of latch circuits XDL is sequentially transferred to the latch circuits in the sense amplifier module SAM in the write operation. The user data Dat included in the latch circuits in the sense amplifier module SAM is sequentially transferred to the latch circuit XDL in the read operation. The user data Dat included in the latch circuit XDL is sequentially transferred to the input/output control circuit I/O in a data-out operation via the column decoder COLD and a multiplexer MPX.

### Configuration of Voltage Generation Circuit VG

For example, as illustrated in FIG. 5, the voltage generation circuit VG (FIG. 4) is connected to a plurality of voltage supply lines 31. The voltage generation circuit VG includes, for example, a step-down circuit, such as a regulator, and a step-up circuit, such as a charge pump circuit 32. These step-down circuit and step-up circuit are each connected to a voltage supply line to which a power supply voltage V_{CC} and a ground voltage V_{SS} (FIG. 4) are applied. These voltage supply lines are connected to, for example, the pad electrodes P described with reference to FIG. 2 and FIG. 3. For example, the voltage generation circuit VG generates a plurality of operating voltages applied to the bit lines BL, the source lines SL, the word lines WL, and the select gate lines (SGD, SGS, SGSb) in the read operation, the write operation, and the erase operation on the memory cell array MCA, in accordance with a control signal from the sequencer SQC to simultaneously output the operating voltages to the plurality of voltage supply lines 31. The operating voltage output from the voltage supply line 31 is appropriately adjusted in accordance with the control signal from the sequencer SQC.

### Configuration of Sequencer SQC

The sequencer SQC (FIG. 4) outputs an internal control signal to the row decoders RD0, RD1, the sense amplifier modules SAM0, SAM1, and the voltage generation circuit VG in response to command data Cmd stored in the command register CMR. The sequencer SQC outputs status data Stt indicating the state of the memory die MD to the status register STR as appropriate. The state of the memory die MD includes a ready/busy state of the memory die MD. Hereinafter, the ready/busy state is simply referred to as a “ready-busy state” in some cases.

The sequencer SQC generates a ready/busy signal and outputs the ready/busy signal to a terminal RY//BY. The terminal RY//BY enters an “L” state during execution of operations of applying a voltage to the memory cell array MCA, such as the read operation, the write operation, and the erase operation, and a get feature, a set feature, and the like. In the case other than them, the terminal RY//BY enters an “H” state. Even when operations, such as a data-out operation and a status-read, in which a voltage is not applied to the memory cell array MCA, are executed, the terminal RY//BY does not enter the “L” state. In a period where the terminal RY//BY is in the “L” state (a busy period), an access to the memory die MD is basically inhibited. In a period where the terminal RY//BY is in the “H” state (a ready period), the access to the memory die MD is permitted. The terminal RY//BY is achieved by, for example, the pad electrode P described with reference to FIG. 2 and FIG. 3.

The sequencer SQC includes a feature register FR. The feature register FR is a register that latches feature data Fd. The feature data Fd includes, for example, control parameters of the memory die MD, and the like.

### Configuration of Address Register ADR

As illustrated in FIG. 4, the address register ADR is connected to the input/output control circuit I/O and stores the address data Add input from the input/output control circuit I/O. The address register ADR includes, for example, a plurality of 8-bit register arrays. For example, when an internal operation, such as the read operation, the write operation, or the erase operation, is executed, the register array latches the address data Add corresponding to the internal operation being executed.

The address data Add includes, for example, the column address CA (FIG. 4) and the row address RA (FIG. 4). The row address RA includes, for example, a block address identifying the memory block BLK (FIG. 5), a page address identifying the string unit SU and the word line WL, a plane address identifying the memory cell array MCA (plane), and a chip address identifying the memory die MD.

### Configuration of Command Register CMR

The command register CMR is connected to the input/output control circuit I/O and stores the command data Cmd input from the input/output control circuit I/O. The command register CMR includes, for example, at least one set of 8-bit register array. When the command data Cmd is stored in the command register CMR, a control signal is transmitted to the sequencer SQC.

### Configuration of Status Register STR

The status register STR is connected to the input/output control circuit I/O and stores the status data Stt output to the input/output control circuit I/O. The status register STR includes, for example, a plurality of 8-bit register arrays. For example, when an internal operation, such as the read operation, the write operation, or the erase operation, is executed, the register array latches the status data Stt related to the internal operation being executed. Further, the register array latches, for example, ready/busy information indicating the ready/busy state of the memory cell arrays MCA0, MCA1.

### Configuration of Data Output Timing Adjustment Circuit TCT

The data output timing adjustment circuit TCT is connected to a bus wiring DB between the cache memories CM0, CM1 and the input/output control circuit I/O. For example, in a case, such as where the data-out operation is continuously executed with respect to the cache memories CM0, CM1, in order to start the data-out operation of the cache memory CM1 without a time interval after completion of the data-out operation of the cache memory CM0, the data output timing adjustment circuit TCT adjusts the start timing of the data-out operation on the cache memory CM1.

### Configuration of Input/Output Control Circuit I/O

The input/output control circuit I/O (FIG. 4) includes data signal input/output terminals DQ0 to DQ7, data strobe signal input/output terminals DQS, /DQS (BDQS), a shift register, and a buffer circuit.

Each of the data signal input/output terminals DQ0 to DQ7 and the data strobe signal input/output terminals DQS, /DQS (BDQS) is achieved by, for example, the pad electrode P described with reference to FIG. 2 and FIG. 3. Data input via the data signal input/output terminals DQ0 to DQ7 are input from the buffer circuit to the cache memory CM in response to an internal control signal from the logic circuit CTR. Data output via the data signal input/output terminals DQ0 to DQ7 are input to the buffer circuit from the cache memory CM or the status register STR in response to the internal control signal from the logic circuit CTR.

Signals (such as, a data strobe signal and its complementary signal) input via the data strobe signal input/output terminals DQS, /DQS (BDQS) are used for the input of the data via the data signal input/output terminals DQ0 to DQ7. The data input via the data signal input/output terminals DQ0 to DQ7 is retrieved in the shift register in the input/output control circuit I/O at a timing of a voltage rising edge of the data strobe signal input/output terminal DQS and a voltage falling edge of the data strobe signal input/output terminal /DQS (BDQS), and at a timing of a voltage falling edge of the data strobe signal input/output terminal DQS and a voltage rising edge of the data strobe signal input/output terminal /DQS (BDQS).

For example, as illustrated in FIG. 8, the data signal input/output terminals DQ0 to DQ7 and the data strobe signal input/output terminals DQS, /DQS (BDQS) are each connected to an input circuit 201 and an output circuit 202. The input circuit 201 is, for example, a receiver, such as a comparator. The output circuit 202 is, for example, a driver, such as an Off Chip Driver (OCD) circuit.

### Configuration of Logic Circuit CTR

The logic circuit CTR (FIG. 4) includes a plurality of control terminals /CE, CLE, ALE, /WE, /RE (BRE), RE, /WP and logic circuits connected to these plurality of control terminals /CE, CLE, ALE, /WE, /RE (BRE), RE, /WP. The logic circuit CTR receives an external control signal from the controller die CD via the control terminals /CE, CLE, ALE, /WE, /RE (BRE), RE, /WP and outputs the internal control signal to the input/output control circuit I/O in response to the external control signal.

For example, as illustrated in FIG. 8, the control terminals /CE, CLE, ALE, /WE, /RE (BRE), RE, /WP are each connected to the input circuit 201. In the illustrated example, the control terminals CLE, ALE, /WP are each further connected to the output circuit 202. The control terminals /CE, CLE, ALE, /WE, /RE (BRE), RE, /WP are each achieved by, for example, the pad electrode P described with reference to FIG. 2 and FIG. 3.

A signal (such as, a chip enable signal) input via the control terminal /CE is used for selection of the memory die MD. The memory die MD in which “L” is input to the control terminal /CE enters a state where an input/output of the user data Dat, the command data Cmd, the address data Add, and the status data Stt (hereinafter, may be simply referred to as “data”) is possible. The memory die MD in which “H” is input to the control terminal /CE enters a state where the input/output of the data is impossible. As illustrated in FIG. 8, the control terminal /CE is connected to the input circuit 201.

A signal (such as, a command latch enable signal) input via the control terminal CLE is used for, for example, the use of the command register CMR. A signal input via the control terminal CA1 (CLE) is used for, for example, the use of the command register CMR, and is also used as the command data Cmd and the address data Add. Further, the status data Stt is output from the status register STR via the control terminal CLE.

A signal (such as, an address latch enable signal) input via the control terminal ALE is used for, for example, the use of the address register ADR. A signal input via the control terminal ALE is used for, for example, the use of the address register ADR, and is also used as the command data Cmd and the address data Add. Further, the status data Stt is output from the status register STR via the control terminal ALE. A signal input via the control terminal ALE is used for, for example, the use of the address register ADR, and is also used as the command data Cmd and the address data Add. Further, the status data Stt is output from the status register STR via the control terminal ALE.

A signal (such as, a write enable signal) input via the control terminal /WE is used, for example, for the input of the data from the controller die CD to the memory die MD.

Signals (such as, a read enable signal and its complementary signal) input via the control terminals /RE (BRE), RE are used for the output of the data via the data signal input/output terminals DQ0 to DQ7. The data output from the data signal input/output terminals DQ0 to DQ7 is switched at a timing of a voltage falling edge (switching of the input signal) of the control terminal /RE (BRE) and a voltage rising edge (switching of the input signal) of the control terminal RE, and at a timing of a voltage rising edge (switching of the input signal) of the control terminal /RE (BRE) and a voltage falling edge (switching of the input signal) of the control terminal RE.

A signal (such as, a write protect signal) input via the control terminal /WP is used, for example, for restriction of the input of the user data Dat from the controller die CD to the memory die MD. The signal input via the control terminal /WP may be used as the command data Cmd and the address data Add, or the status data Stt may be output from the status register STR via the control terminal /WP.

### Operations of Memory Die MD

Next, operations of the memory die MD are described.

The memory die MD is configured to be able to perform the read operation. The read operation is an operation where the user data Dat is read from the memory cell array MCA by the sense amplifier module SAM and the read user data Dat is transferred to the latch circuit XDL. In the read operation, the user data Dat read from the memory cell array MCA is transferred to the latch circuit XDL via the bit line BL and the sense amplifier module SAM.

The memory die MD is configured to be able to perform the data-out operation. The data-out operation of the user data Dat is an operation where the user data Dat included in the latch circuit XDL is output to the controller die CD. In the data-out operation of the user data Dat, the user data Dat included in the latch circuit XDL is output to the controller die CD via the column decoder COLD, the multiplexer MPX, the bus wiring DB, and the input/output control circuit I/O described with reference to FIG. 7.

The memory die MD is configured to be able to perform the status-read. The status-read is an operation where the status data Stt included in the status register STR is output to the controller die CD. In the status-read, the status data Stt included in the status register STR is output to the controller die CD via the logic circuit CTR.

The memory die MD is configured to be able to perform the get feature (a characteristic information output operation). The get feature is an operation where the feature data Fd included in the feature register FR (FIG. 4) is output to the controller die CD (FIG. 1). In the get feature, the feature data Fd included in the feature register FR is output to the controller die CD via the logic circuit CTR.

The memory die MD is configured to be able to perform the set feature. The set feature is an operation where the feature data Fd is input to the feature register FR (FIG. 4). In the set feature, the feature data Fd is input to the feature register FR from the controller die CD via the logic circuit CTR.

The memory die MD is configured to be able to perform a write data training operation.

Here, as described above, the data input via the data signal input/output terminals DQ0 to DQ7 is retrieved in the shift register in the input/output control circuit I/O at the voltage switch timing of the data strobe signal input/output terminals DQS, /DQS (BDQS). Therefore, the controller die CD usually switches the voltage of the data strobe signal input/output terminals DQS, /DQS (BDQS) in a state where the data is input to the data signal input/output terminals DQ0 to DQ7. It is preferred that a time period from the switch of the signal input to the data signal input/output terminals DQ <7:0> to the switch of the signal (data strobe signal) input to the data strobe signal input/output terminals DQS, /DQS (BDQS) is equal to a time period from the switch of the signal (data strobe signal) input to the data strobe signal input/output terminals DQS, /DQS (BDQS) to the switch of the signal input to the data signal input/output terminals DQ <7:0>. Here, an optimal value of a time period (hereinafter referred to as “Skew” in some cases) from the input of data to the data signal input/output terminals DQ0 to DQ7 to the switch of the voltage of the data strobe signal input/output terminals DQS, /DQS (BDQS) varies depending on the operation condition, such as temperature, in some cases.

As described with reference to FIG. 8, the data signal input/output terminals DQ0 to DQ7 are connected to the input circuits 201, such as a comparator. Therefore, when the voltage of the data signal input/output terminals DQ0 to DQ7 is greater than a reference voltage of the input circuit 201, “1” is output from the input circuit 201, and when the voltage of the data signal input/output terminals DQ0 to DQ7 is smaller than the reference voltage of the input circuit 201, “0” is output from the input circuit 201. However, an optimal value of the reference voltage of the input circuit 201 varies depending on the operation condition, such as temperature, in some cases.

In the write data training operation, the data input from the controller die CD to the memory die MD and the bit error detection are performed while sequentially switching Skew and the reference voltage of the input circuit 201, thereby detecting the optimal values of Skew and the reference voltage of the input circuit 201. The write data training operation is executed, for example, when the memory die MD is powered on, and when the temperature or the power supply voltage (VCCQ and the like) varies.

### Write Data Training Operation

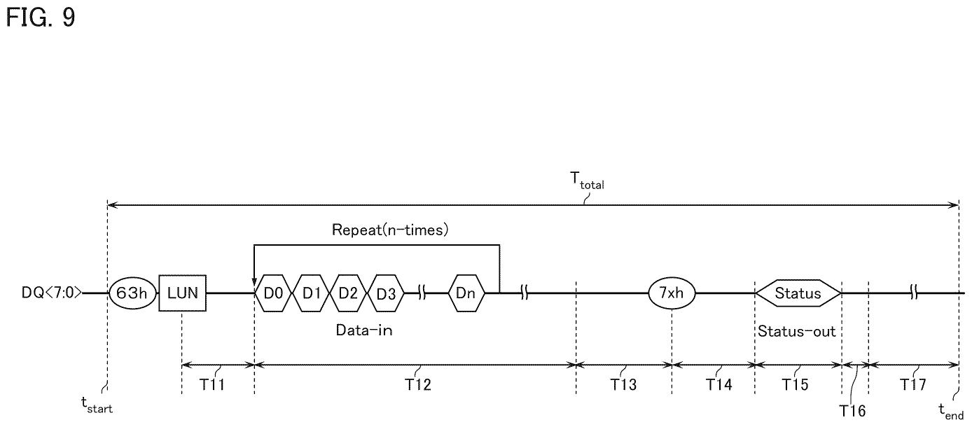

FIG. 9 is a schematic timing chart illustrating a state of executing the write data training operation (Write DQ training operation). In the write data training operation according to the embodiment, first, expected value data (pattern data) is input to the memory die MD. The expected value data is input over a sufficient time so as not to cause the bit error. For example, after sufficiently waiting for the signal of the data signal input/output terminals DQ <7:0> reaching the value “L” or “H”, the voltage of the data strobe signal input/output terminals DQS, /DQS (BDQS) is switched. Next, while sequentially switching Skew and the reference voltage of the input circuit 201, the same data (pattern data) as the expected value data (hereinafter referred to as “test data” in some cases) is input from the controller die CD to the memory die MD multiple times. The input of the test data is executed, for example, in the similar aspect of normal data-in when the write operation is executed. When Skew and the reference voltage of the input circuit 201 are appropriate, the bit error does not occur at the data-in, and the expected value data and the test data are matched. When at least one of Skew and the reference voltage of the input circuit 201 is inappropriate, the bit error occurs at the data-in, and the expected value data and the test data are unmatched at some positions.

In this embodiment, different LUN (Logical Unit Number) addresses of LUN0, LUN1 are assigned to the respective memory dies MD, and the memory die MD can be identified with the LUN address. In other words, the two respective memory dies MD included in the memory system 10 are configured to function as LUN0, LUN1. In the following description, the LUN address assigned to the memory die MD is referred to as LUN.

In this embodiment, as illustrated in FIG. 9, at a start (time tₛₜₐᵣₜ) of the write data training operation, command data “63h” and the LUN address “LUN” are sequentially input from the controller die CD to the memory die MD via the data signal input/output terminals DQ0 to DQ7. The command data “63h” is command data Cmd that instructs the data-in (write operation) in the write data training operation. The LUN address “LUN” included in this command set includes information on the memory cell array MCA (FIG. 4) as a target of the write operation.

After the LUN address “LUN” is input, the same data as the expected value data for the memory die MD is input from the controller die CD to the memory die MD via the data signal input/output terminals DQ <7:0>. The input data is compared with the expected value data latched in the memory die MD in real time. Here, the input data is user data Dat, in which data patterns (data D0 to Dn) having a predetermined bit length are repeated n times. The data pattern having the predetermined bit length is determined based on a specification of the write data training. Time period T11 is a time period from the input of the LUN address “LUN” to the start of the data pattern input, and time period T12 is a time period, for example, taken for repeatedly inputting the data patterns (data D0 to Dn) having the predetermined bit length n times and performing the comparison with the expected value latched in the memory die MD.

After the test data (data pattern) is input, command data “7xh” is input from the controller die CD to the memory die MD via the data signal input/output terminals DQ0 to DQ7. The command data “7xh” is command data Cmd that instructs the status-read. After the command data “7xh” is input, the status-read is executed, for example, in the memory die MD specified by the LUN address.

Time period T13 is a time period from the input of the test data (data pattern) to the input of the command data “7xh”. Time period T14 is a time period from the input of the command data “7xh” to the execution of the status-read. Time period T15 is a time period taken for the execution of the status-read. When the status-read is executed, a comparison result between the input data and the expected value latched in the memory die MD is output as the status data Stt.

Time period T17 is a time period taken for acquiring the comparison result and performing Pass/Fail determination by the controller die CD. The controller die CD can perform the Pass/Fail determination using the comparison result (status data Stt) acquired through the status-read. Time period T16 is a time period from the output of the comparison result from the status register STR to the start of the Pass/Fail determination.

Time period Tₜₒₜₐₗ is a time period taken for the write data training operation from the start (time tₛₜₐᵣₜ) of the write data training operation to an end of time period T17, that is, end time t_{end} of the Pass/Fail determination.

### Write Data Training Operation in Comparative Example

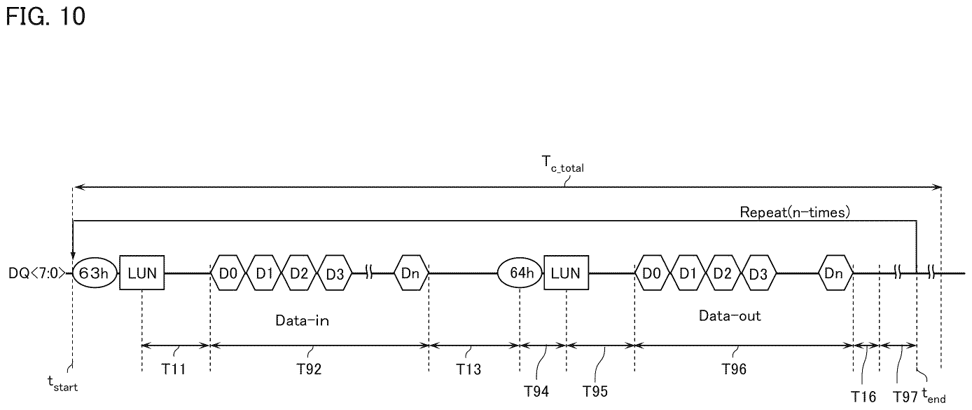

FIG. 10 is a schematic timing chart illustrating a state of the write data training operation according to a comparative example.

In the comparative example, as illustrated in FIG. 10, at a start (time tₛₜₐᵣₜ) of the write data training operation, the command data “63h” and the LUN address “LUN” are sequentially input from the controller die CD to the memory die MD via the data signal input/output terminals DQ0 to DQ7.

After the LUN address “LUN” is input, the data patterns (data D0 to Dn) having the predetermined bit length are input from the controller die CD to the memory die MD via the data signal input/output terminals DQ <7:0>. Time period T92 is a time period, for example, taken for the input of the data patterns (data D0 to Dn) having the predetermined bit length.

After the data patterns (data D0 to Dn) having the predetermined bit length are input, command data “64h” and the LUN address “LUN” are sequentially input from the controller die CD to the memory die MD via the data signal input/output terminals DQ0 to DQ7. The command data “64h” is command data Cmd that instructs data-out.

After the input of the command data “64h”, the data-out of the input data (data D0 to Dn) is executed in the memory die MD specified by the LUN address.

Time period T94 is a time period from the input of the command data “64h” to the input of the LUN address “LUN”. Time period T95 is a time period from the input of the LUN address “LUN” to the execution of the data-out, and is as long as time period T14. Time period T96 is a time period taken for the execution of the data-out of the input data (data D0 to Dn), and is longer than time period T16. When the data-out is executed, the input data is read by the controller die CD. In time period T97, the controller die CD compares the read data with the expected value data latched in the controller die CD, and performs the Skew adjustment of the data strobe signal input to the data strobe signal input/output terminal DQS and the data input to the data signal input/output terminals DQ <7:0> and the adjustment of a reference voltage VREF of the memory die MD based on whether or not the read data and the expected value data are matched.

After the end of time period T97, a sequence of operations from the input of the command data “63h” at time tₛₜₐᵣₜ to end time t_{end} of time period T97 is repeatedly performed n times.

Time period T_{c_total} is a time period taken for completing the write data training operation. Time period Tₜₒₜₐₗ is a time period taken for repeatedly performing the sequence of operations from the input of the command data “63h” at time tₛₜₐᵣₜ to end time t_{end} of time period T97 n times. Therefore, time period T_{c_total} is longer than time period Tₜₒₜₐₗ.

### Effects and the Like

During the execution of the data-in and the data-out, the bus wirings connected to the data signal input/output terminals DQ <7:0> between the controller die CD and the memory die MD are used. Therefore, during the execution of the write data training operation, another memory die MD connected to the same bus wiring cannot execute the data-in or the data-out. Accordingly, the time period taken for executing the write data training operation becomes a time overhead of the memory system 10.

In the write data training operation according to the comparative example, the data used for the comparison with the expected value corresponds to only the data patterns (data D0 to Dn) having the predetermined bit length determined by the specification. Therefore, when the data pattern having the bit length longer than the predetermined bit length is used for the comparison with the expected value, as described in FIG. 10, since it is necessary to repeatedly perform a sequence of the operations from the input of the command data “63h” at time tₛₜₐᵣₜ to end time t_{end} of time period T97 and it takes a long time for this, the time overhead of the memory system 10 increases.

Therefore, in the write data training operation according to the embodiment, the expected value data is latched in not the controller die CD but the memory die MD, and the comparison of the data input by the data-in with the expected value data is performed by the memory die MD. The comparison result is output as the status data Stt. This eliminate the need for time period T94 and time period T96 repeated in the comparative example, and therefore, the time overhead of the memory system 10 in the write data training operation can be decreased.

Further, in the write data training operation according to the embodiment, during the execution of the data-in, the data of the data patterns (data D0 to Dn) having the predetermined bit length and repeated n times can be input and compared with the expected value data. This allows using the data pattern having the bit length exceeding the predetermined bit length determined by the specification.

### Exemplary Configuration of Input/Output Control Circuit I/O

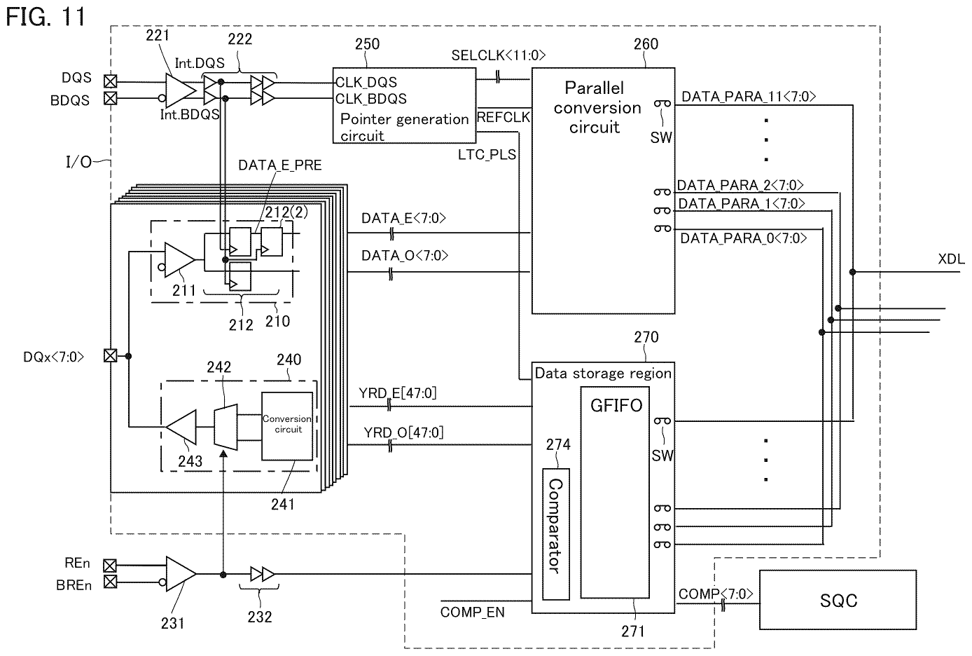

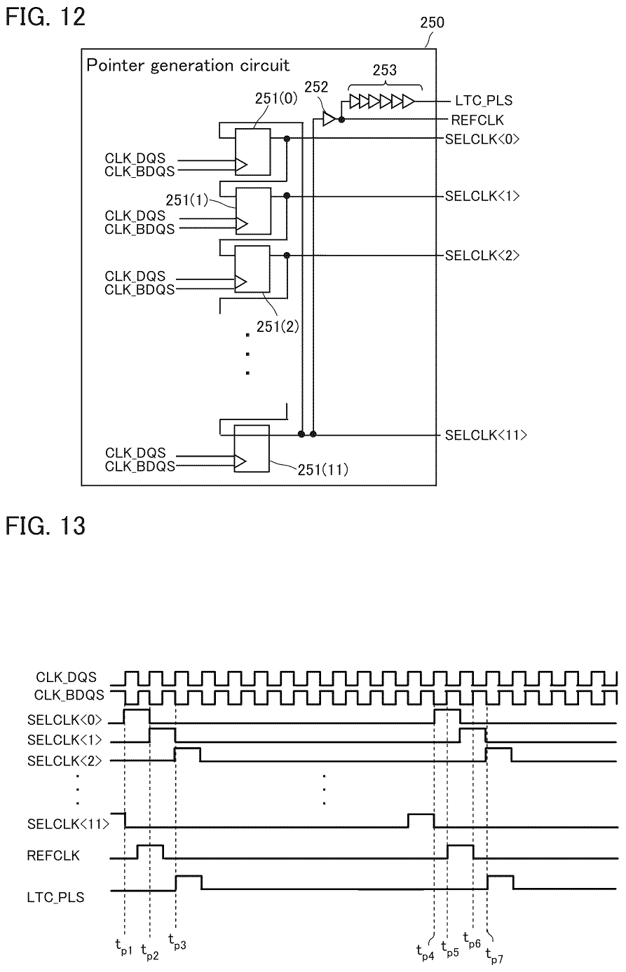

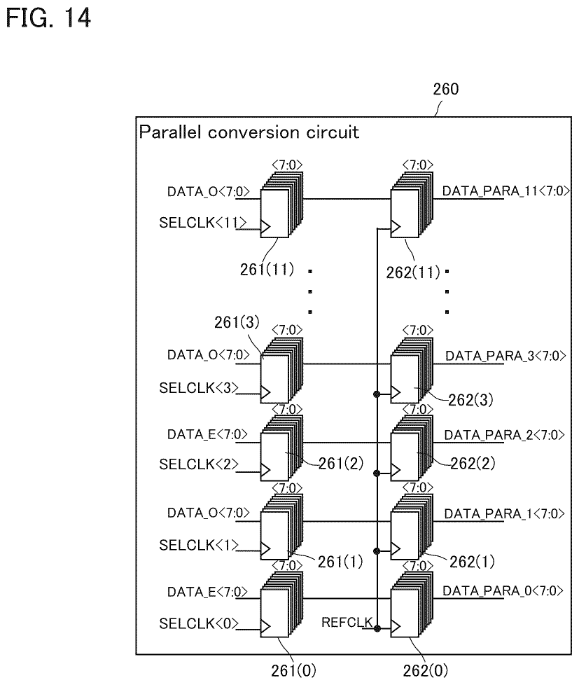

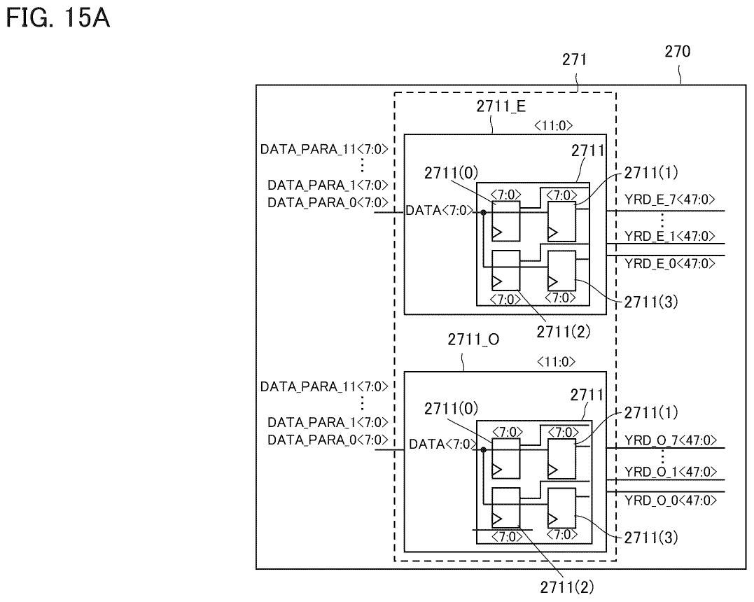

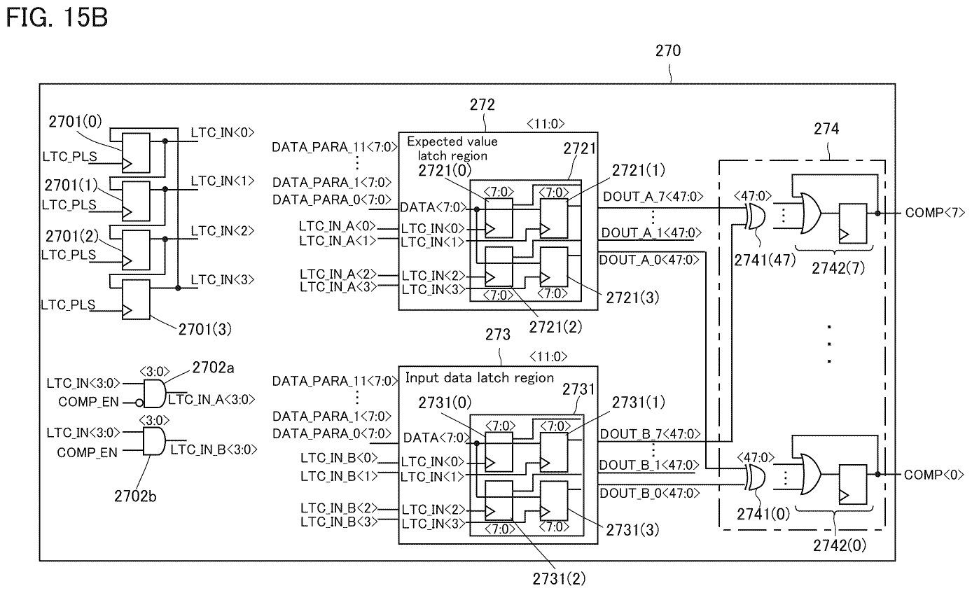

Next, the configuration of the input/output control circuit I/O to achieve the write data training operation according to the embodiment is described. FIG. 11 is a schematic circuit diagram illustrating an exemplary configuration of the input/output control circuit I/O. FIG. 12 is a schematic circuit diagram illustrating an exemplary configuration of a pointer generation circuit 250 according to the embodiment. FIG. 13 is a schematic waveform diagram illustrating an input/output signal of the pointer generation circuit 250 according to the embodiment. FIG. 14 is a schematic circuit diagram illustrating an exemplary configuration of a parallel conversion circuit 260 according to the embodiment. FIG. 15A and FIG. 15B are schematic circuit diagrams illustrating an exemplary configuration of the data storage region 270 according to the embodiment.

The input/output control circuit I/O (FIG. 4) includes, for example, as illustrated in FIG. 11, an input circuit 210 and an output circuit 240 connected to the data signal input/output terminals DQ <7:0>, a comparator 221 connected to the data strobe signal input/output terminals DQS, BDQS, a signal propagation circuit 222 that propagates an output signal of the comparator 221, the pointer generation circuit 250, the parallel conversion circuit 260, and the data storage region 270. FIG. 11 illustrates also a comparator 231 connected to control terminals REn, BREn and a signal propagation circuit 232 that propagates an output signal of the comparator 231 as a part of the circuits of the logic circuit CTR.

### Exemplary Configuration of Comparator 221 and Signal Propagation Circuit 222

The comparator 221 has one input terminal connected to the data strobe signal input/output terminal DQS and the other input terminal connected to the data strobe signal input/output terminal BDQS. The signal propagation circuit 222 propagates output signals Int.DQS, Int.BDQS of the comparator 221. The output signals Int.DQS, Int.BDQS propagated by the signal propagation circuit 222 are clock signals input via the data strobe signal input/output terminals DQS, BDQS. A signal CLK_BDQS is an inverted signal of a signal CLK_DQS. The output signals Int.DQS, Int.BDQS are input to the pointer generation circuit 250 as the signals CLK_DQS, CLK_BDQS.

### Exemplary Configuration of Input Circuit 210

The input circuit 210 includes a comparator 211 connected to the data signal input/output terminals DQ <7:0> and a circuit element 212 that latches data. The input circuit 210 is disposed corresponding to (the number of) the data signal input/output terminals DQ0 to DQ7. The comparator 211 has the same configuration as the input circuit 201 described with reference to FIG. 8, and has one input terminal connected to any of the data signal input/output terminals DQ0 to DQ7 and the other input terminal to which the reference voltage VREF is applied. The circuit element 212 includes, for example, three latch circuits including an odd (odd number) latch circuit and an even (even number) latch circuit. One latch circuit outputs the output signal Int.DQS as a latch enable signal, and latches an output signal of the comparator 211 at the timing of DQS rise and BDQS fall. The other two latch circuits output the output signal Int.BDQS as a latch enable signal, latch data of the above-described latch circuit and an output signal of the comparator 211 at the timing of DQS fall and BDQS rise, and output the latched data and output signal as even number data DATA_E <7:0> and odd number data DATA_O <7:0> to the parallel conversion circuit 260. Thus, the input circuit 210 can output 8-bit data input to the data signal input/output terminals DQ <7:0> to the parallel conversion circuit 260 by converting the 8-bit data into 16-bit data.

### Exemplary Configuration of Comparator 231 and Signal Propagation Circuit 232

The comparator 231 has one input terminal connected to the control terminal RE and the other input terminal connected to the control terminal BRE. The signal propagation circuit 232 propagates an output signal of the comparator 231. The output signal propagated by the signal propagation circuit 232 is input to the data storage region 270.

### Exemplary Configuration of Output Circuit 240

The output circuit 240 includes a conversion circuit 241 configured to latch input data to convert the 96-bit data into 12-bit data, a demultiplexer 242, and a comparator 243. The output circuit 240 operates when the data-out is executed. When the data-out is executed, a data latch unit GFIFO (Global First-in First-out) 271 of the data storage region 270 temporarily latches a plurality of pieces of data transferred from a plurality of latch circuits XDL, and outputs the data in the order of latching. The conversion circuit 241 latches each piece of, for example, the 96-bit data (YRD_E[47:0], YRD_O[47:0]) output from the data latch unit GFIFO 271 of the data storage region 270 as 12-bit data, and outputs the latched data to the demultiplexer 242. The conversion circuit 241 functions as also LFIFO (Local First-in First-out). The demultiplexer 242 performs serial conversion of the 12-bit data corresponding to the output signal of the comparator 231, and outputs the converted data to the comparator 243. The comparator 243 has the same configuration as the output circuit 202 described with reference to FIG. 8, and has one input terminal connected to the output terminal of the demultiplexer 242 and the other input terminal to which the reference voltage VREF is applied. The comparator 243 outputs the data output from the demultiplexer 242 to the data signal input/output terminals DQ <7:0>. Thus, the output circuit 240 can output, for example, the 96-bit data output from the data latch unit GFIFO 271 of the data storage region 270 to the data signal input/output terminals <7:0> by converting the 96-bit data into 8-bit data.

### Exemplary Configuration of Pointer Generation Circuit 250

The pointer generation circuit 250 (FIG. 11) is a circuit for distributing data when the serial conversion is performed. The pointer generation circuit 250 (FIG. 11) includes, for example, as illustrated in FIG. 12, a plurality of latch circuits 251 (0) to 251 (11), a buffer circuit 252, and a signal propagation circuit 253.

The plurality of latch circuits 251 (0) to 251 (11) receive the signal CLK_DQS or CLK_BDQS as the latch enable signal, and output signals SELCLK <0> to SELCLK <11> to the parallel conversion circuit 260. As illustrated in the example of FIG. 13, the signal SELCLK <0> corresponding to the latch circuit 251 (0) rises at a timing of the rise of the signal CLK_DQS and the fall of the signal CLK_BDQS at time tₚ₁, and falls at a timing of the rise of the signal CLK_DQS and the fall of the signal CLK_BDQS at time tₚ₂. Similarly, the signal SELCLK <1> corresponding to the latch circuit 251 (1) rises at a timing of the rise of the signal CLK_DQS and the fall of the signal CLK_BDQS at time tₚ₂, and falls at a timing of the rise of the signal CLK_DQS and the fall of the signal CLK_BDQS at time tₚ₃. Since the same applies to the latch circuits 251 (2) to 251 (11), the explanation is omitted.

The buffer circuit 252 is connected to the output terminal of the latch circuit 251 that outputs the signal SELCLK <11>, delays the signal SELCLK <11> output from the latch circuit 251, and outputs the delayed signal SELCLK <11> to the parallel conversion circuit 260 as a signal REFCLK. The signal REFCLK is a clock signal for adjusting a timing of collectively outputting the data of the signals SELCLK <0> to <11>. In the example illustrated in FIG. 13, the signal REFCLK of the buffer circuit 252 rises at a timing of the fall of the signal CLK_DQS and the rise of the signal CLK_BDQS at time tₚ₅ after time tₚ₄ at which the latch circuit 251 (11) outputs the signal SELCLK <11>. At the timing of rising edge of the signal REFCLK at time tₚ₅, the data of the signals SELCLK <0> to <11> is output to the parallel conversion circuit 260.

The signal propagation circuit 253 is connected to the output terminal of the buffer circuit 252, delays the signal REFCLK output from the buffer circuit 252, and outputs the delayed signal REFCLK to the data storage region 270 as a signal LTC_PLS. The signal LTC_PLS is a clock signal used in the data storage region 270. In the example illustrated in FIG. 13, the signal propagation circuit 253 outputs the signal LTC_PLS to the data storage region 270 at a timing of the rise of the signal CLK_DQS and the fall of the signal CLK_BDQS at time tₚ₇ after the output of the signal REFCLK by the buffer circuit 252 (time tₚ₆).

### Exemplary Configuration of Parallel Conversion Circuit 260

The parallel conversion circuit 260 (FIG. 11) is a circuit that converts a serial signal into a parallel signal. The parallel conversion circuit 260 includes, for example, as illustrated in FIG. 14, a plurality of latch circuits 261 (0) <7:0> to 261 (11) <7:0> and a plurality of latch circuits 262 (0) <7:0> to 262 (11) <7:0>.

At an output terminal of the parallel conversion circuit 260, a plurality of switches SW are disposed. When these plurality of switches SW are in an ON state, data DATA_PARA_0 <7:0> to data DATA_PARA_11 <7:0> are output from the parallel conversion circuit 260.

The latch circuits 261 (0) <7:0> receive the signal SELCLK <0> as the latch enable signal, receive data DATA_E <7:0> as the input signal, and output the output signal to the latch circuits 262 (0) <7:0>. The latch circuits 261 (1) <7:0> receive the signal SELCLK <1> as the latch enable signal, receive data DATA_O <7:0> as the input signal, and output the output signal to the latch circuits 262 (1) <7:0>. The latch circuits 261 (2) <7:0> receive the signal SELCLK <2> as the latch enable signal, receive data DATA_E <7:0> as the input signal, and output the output signal to the latch circuits 262 (2) <7:0>. The latch circuits 261 (3) <7:0> receive the signal SELCLK <3> as the latch enable signal, receive data DATA_O <7:0> as the input signal, and output the output signal to the latch circuits 262 (3) <7:0>. The latch circuits 261 (11) <7:0> receive the signal SELCLK <11> as the latch enable signal, receive data DATA_O <7:0> as the input signal, and output the output signal to the latch circuits 262 (11) <7:0>. Since the same applies to the latch circuits 261 (4) <7:0> to (10) <7:0>, the explanation is omitted.

The latch circuits 262 (0) <7:0> receive the signal REFCLK as the latch enable signal, receive the output of the latch circuits 261 (0) <7:0> as the input signal, and output the data DATA_PARA_0 <7:0> as an output signal. The latch circuits 262 (1) <7:0> receive the signal REFCLK as the latch enable signal, receive the output of the latch circuits 261 (1) <7:0> as the input signal, and output the data DATA_PARA_1 <7:0> as an output signal. The latch circuits 262 (2) <7:0> receive the signal REFCLK as the latch enable signal, receive the output of the latch circuits 261 (2) <7:0> as the input signal, and output the data DATA_PARA_2 <7:0> as an output signal. The latch circuits 262 (3) <7:0> receive the signal REFCLK as the latch enable signal, receive the output of the latch circuits 261 (3) <7:0> as the input signal, and output the data DATA_PARA_3 <7:0> as an output signal. The latch circuits 262 (11) <7:0> receive the signal REFCLK as the latch enable signal, receive the output of the latch circuits 261 (11) <7:0> as the input signal, and output the data DATA_PARA_11 <7:0> as an output signal. Since the same applies to the latch circuits 262 (4) <7:0> to (10) <7:0>, the explanation is omitted. Thus, the parallel conversion circuit 260 can convert, for example, the 16-bit data (DATA_O <7:0>, data DATA_E <7:0>) into the 96-bit data (data DATA_PARA_0 <7:0> to data DATA_PARA_11 <7:0>).

### Exemplary Configuration of Data Storage Region 270

The data storage region 270 (FIG. 11) includes the data latch unit GFIFO 271 and a comparator 274. The data latch unit GFIFO 271 functions as also an expected value latch region 272 and an input data latch region 273. The data storage region 270 further includes, for example, as illustrated in FIG. 15B, a plurality of latch circuits 2701 (0) to 2701 (3) and AND circuits 2702a, 2702b. The comparator 274 may be provided outside the data storage region 270.

At an input terminal of the data storage region 270, a plurality of switches SW are disposed. When these plurality of switches SW are in an ON state, data DATA_PARA_0 <7:0> to data DATA_PARA_11 <7:0> are input to the data storage region 270.

The plurality of latch circuits 2701 (0) to 2701 (3) receive the signal LTC_PLS as the latch enable signal, and output the signals LTC_PLS <0> to <3>. The AND circuit 2702a constitutes a signal generation circuit together with the plurality of latch circuits 2701 (0) to 2701 (3). The AND circuit 2702a has one input terminal to which output signals LTC_IN <3:0> of the plurality of the latch circuits 2701 (0) to 2701 (3) are input, the other input terminal to which an inverted signal of a signal COMP_EN is input, and an output terminal that outputs signals LTC_IN_A <3:0>. The signals LTC_IN_A <3:0> are input to a latch circuit in the expected value latch region 272. The AND circuit 2702b constitutes a signal generation circuit together with the plurality of latch circuits 2701 (0) to 2701 (3). The AND circuit 2702b has one input terminal to which output signals LTC_IN <3:0> of the plurality of the latch circuits 2701 (0) to 2701 (3) are input, the other input terminal to which the signal COMP_EN is input, and an output terminal that outputs signals LTC_IN_B <3:0>. The signals LTC_IN_B <3:0> are input to a latch circuit in the input data latch region 273.

The data latch unit GFIFO 271 includes, as illustrated in FIG. 15A, an even number data latch unit 2711_E and an odd number data latch unit 2711_O. Each of the even number data latch unit 2711_E and the odd number data latch unit 2711_O includes 4×12 stages of latch circuits 2711, that is, four latch circuits 2711 (0) to 2711 (3) for every data DATA_PARA_0 <7:0> to data DATA_PARA_11 <7:0>.

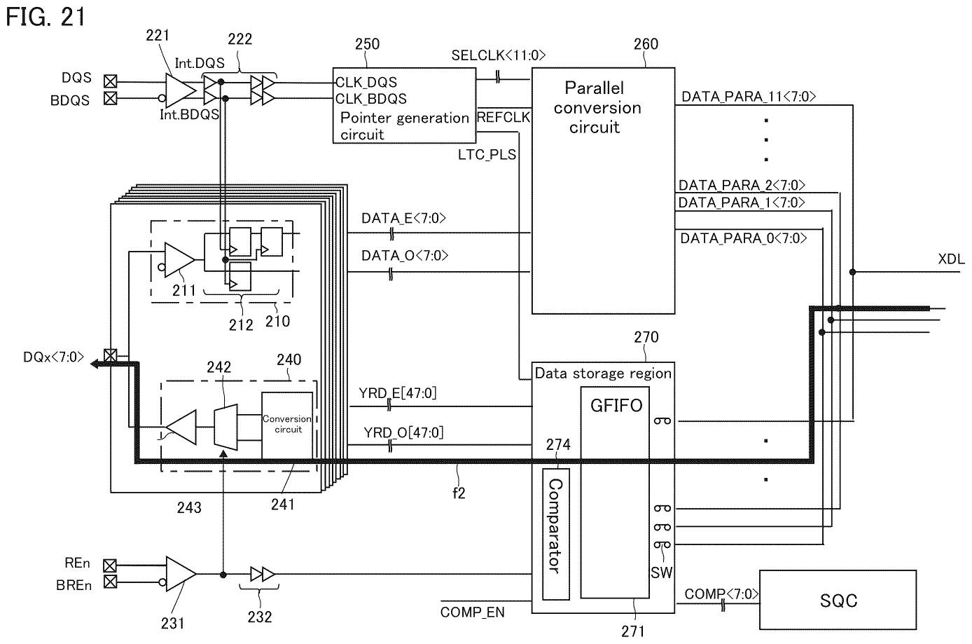

In the data-out (see FIG. 21), the even number data latch unit 2711_E and the odd number data latch unit 2711_O of the data latch unit GFIFO 271 output data YRD_E [47:0] and data YRD_O [47:0] to the conversion circuit (LFIFO) 241 of the output circuit 240 (FIG. 11), respectively corresponding to a pointer signal.

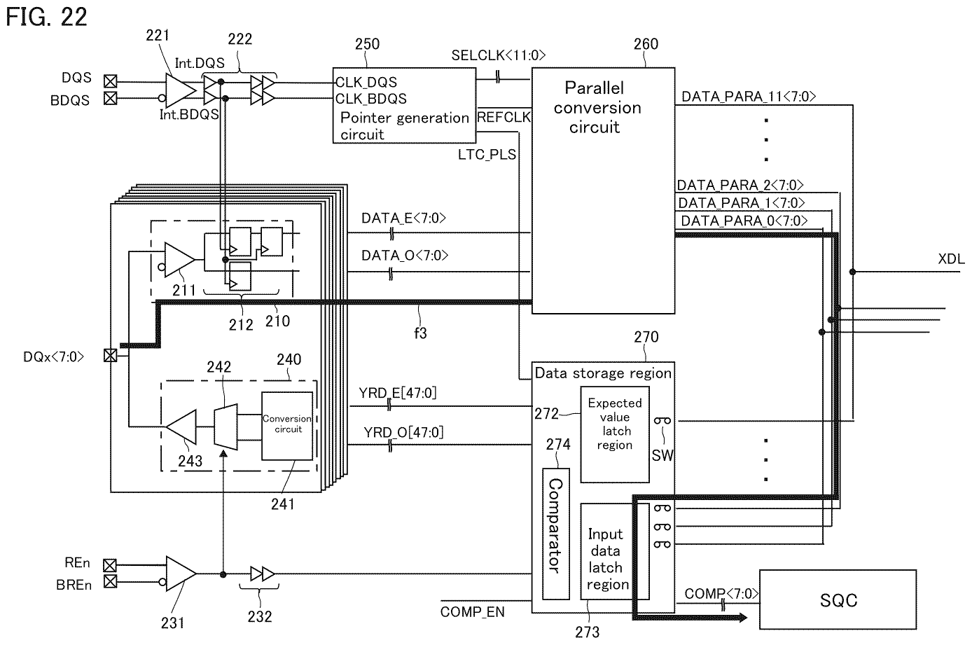

In the data training operation (see FIG. 22), the data latch unit GFIFO 271 functions as, as illustrated in FIG. 15B, the expected value latch region 272 and the input data latch region 273.

The expected value latch region 272 is one of halves of the data latch unit GFIFO 271. The expected value latch region 272 functions as a part of a buffer memory in the data-out operation. The expected value latch region 272 latches the expected value data in the write data training operation. The expected value latch region 272 receives the signal LTC_IN_A <0> to the signal LTC_IN_A <3>, receives the data DATA_PARA_0 <7:0> to the data DATA_PARA_11 <7:0>, and latches the received data as the expected value. The expected value latch region 272 outputs data DOUT_A_0 <47:0> to data DOUT_A_7 <47:0>. The expected value latch region 272 includes 4×12 stages of latch circuits 2721, that is, four latch circuits 2721 (0) to 2721 (3) for every data DATA_PARA_0 <7:0> to data DATA_PARA_11 <7:0>.

The latch circuit 2721 (0) in the first stage receives the signal LTC_IN_A <0> (in the drawing, LTC_IN <0>) as the latch enable signal, receives, for example, data DATA_PARA_0 <7:0> (in the drawing, data DATA <7:0>) as the input signal, and latches the received data. The latch circuit 2721 (1) in the first stage receives the signal LTC_IN_A <1> (in the drawing, LTC_IN <1>) as the latch enable signal, receives, for example, data DATA_PARA_0 <7:0> (in the drawing, data DATA <7:0>) as the input signal, and latches the received data. The latch circuit 2721 (2) in the first stage receives the signal LTC_IN_A <2> (in the drawing, LTC_IN <2>) as the latch enable signal, receives, for example, data DATA_PARA_0 <7:0> (in the drawing, data DATA <7:0>) as the input signal, and latches the received data. The latch circuit 2721 (3) in the first stage receives the signal LTC_IN_A <3> (in the drawing, LTC_IN <3>) as the latch enable signal, receives, for example, data DATA_PARA_0 <7:0> (in the drawing, data DATA <7:0>) as the input signal, and latches the received data. Since the same applies to the latch circuits 2721 (0) to 2721 (3) in the second stage to the twelfth stage, the explanation is omitted.

The input data latch region 273 is the other half of the data latch unit GFIFO 271. The input data latch region 273 functions as a part of a buffer memory in the data-out operation. The input data latch region 273 latches the test data in the write data training operation. The input data latch region 273 receives the signal LTC_IN_B <0> to the signal LTC_IN_B <3>, receives the data DATA_PARA_0 <7:0> to the data DATA_PARA_11 <7:0>, and latches the received data as the test data. The input data latch region 273 outputs data DOUT_B_0 <47:0> to data DOUT_B_7 <47:0>. The input data latch region 273 includes 4×12 stages of latch circuits 2731, that is, four latch circuits 2731 (0) to 2731 (3) for every data DATA_PARA_0 <7:0> to data DATA_PARA_11 <7:0>.

The latch circuit 2731 (0) in the first stage receives the signal LTC_IN_B <0> (in the drawing, LTC_IN <0>) as the latch enable signal, receives, for example, data DATA_PARA_0 <7:0> (in the drawing, data DATA <7:0>) as the input signal, and latches the received data. The latch circuit 2731 (1) in the first stage receives the signal LTC_IN_B <1> (in the drawing, LTC_IN <1>) as the latch enable signal, receives, for example, data DATA_PARA_0 <7:0> (in the drawing, data DATA <7:0>) as the input signal, and latches the received data. The latch circuit 2731 (2) in the first stage receives the signal LTC_IN_B <2> (in the drawing, LTC_IN <2>) as the latch enable signal, receives, for example, data DATA_PARA_0 <7:0> (in the drawing, data DATA <7:0>) as the input signal, and latches the received data. The latch circuit 2731 (3) in the first stage receives the signal LTC_IN_B <3> (in the drawing, LTC_IN <3>) as the latch enable signal, receives, for example, data DATA_PARA_0 <7:0> (in the drawing, data DATA <7:0>) as the input signal, and latches the received data. Since the same applies to the latch circuits 2731 (0) to 2731 (3) in the second stage to the twelfth stage, the explanation is omitted.

The latch circuit 2721 included in the expected value latch region 272 and the latch circuit 2731 included in the input data latch region 273 correspond to the latch circuit 2711 included in the data latch unit GFIFO 271. That is, the expected value latch region 272 and the input data latch region 273 according to the embodiment are achieved by diverting the configuration of the data latch unit GFIFO 271.

The comparator 274 compares the expected value data latched in the expected value latch region 272 with the data latched in the input data latch region 273. The comparator 274 compares the data DOUT_A_0 <47:0> to the data DOUT_A_7 <47:0> of the expected value output from the expected value latch region 272 with the data DOUT_B_0 <47:0> to the data DOUT_B_7 <47:0> output from the input data latch region 273, latches the comparison result as a signal COMP <0> to a signal COMP <7>, and outputs the signal COMP <0> to the signal COMP <7> to the sequencer SQC.

The comparator 274 includes a plurality of XOR circuits 2741 (0) <47:0> to 2741 (7) <47:0> and circuit elements 2742 (0) to 2742 (7).

The XOR circuit 2741 (0) <47:0> has one input terminal to which the data DOUT_A_0 <47:0> is input, and the other input terminal to which the data DOUT_B_0 <47:0> is input. The XOR circuit 2741 (7) <47:0> has one input terminal to which the data DOUT_A_7 <47:0> is input, and the other input terminal to which the data DOUT_B_7 <47:0> is input. Since the same applies to the XOR circuits 2741 (1) <47:0> to 2741 (6) <47:0>, the explanation is omitted. The XOR circuits 2741 (0) <47:0> to 2741 (7) <47:0> can output the comparison result indicating whether or not the expected value data matches the test data. The XOR circuit 2741 (0) <47:0> corresponds to the data input via the data signal input/output terminal DQ0. Similarly, the XOR circuits 2741 (1) <47:0> to 2741 (7) <47:0> correspond to the data input via the data signal input/output terminals DQ1 to DQ7.

Each of the plurality of circuit elements 2742 (0) to 2742 (7) includes an OR circuit and a latch circuit. The OR circuit in the circuit element 2742 (0) receives the output signal of the XOR circuit 2741 (0) <47:0> and the output signal of the latch circuit in the circuit element 2742 (0). Therefore, the output signal of this OR circuit turns “0” only when the 48-bit data DOUT_A_0 <47:0> all matches the 48-bit data DOUT_B_0 <47:0>, respectively and the latch circuit outputs “0”, and otherwise turns “1”. The latch circuit in the circuit element 2742 (0) latches the output signal of the OR circuit, and outputs this output signal to the sequencer SQC as the signal COMP <0>. The circuit elements 2742 (1) to 2742 (7) similarly output the signals COMP <1> to COMP <7> to the sequencer SQC, respectively. The sequencer SQC stores the signals COMP <7:0> in the status register STR as the status data Stt.

### Operation of Input/Output Control Circuit I/O

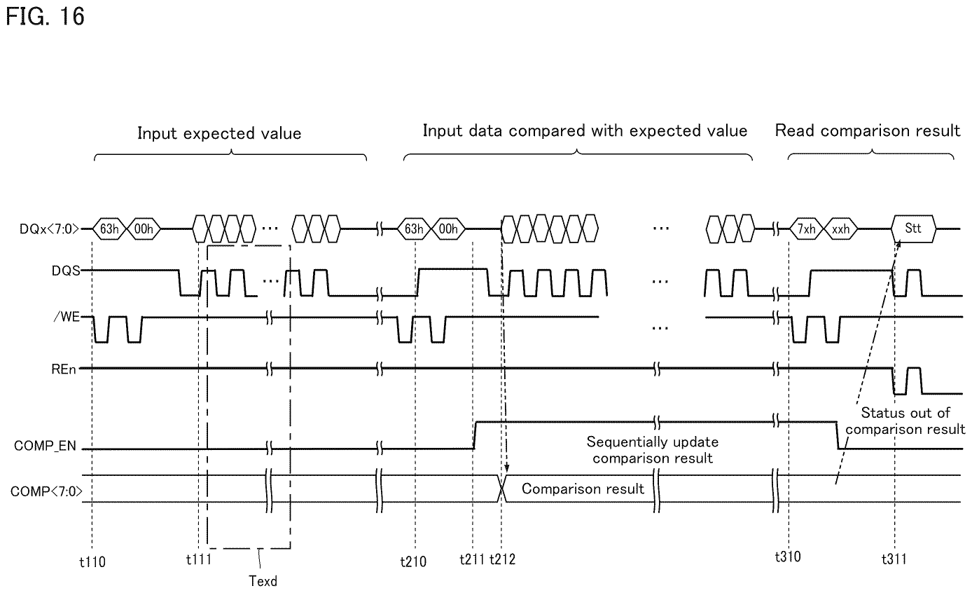

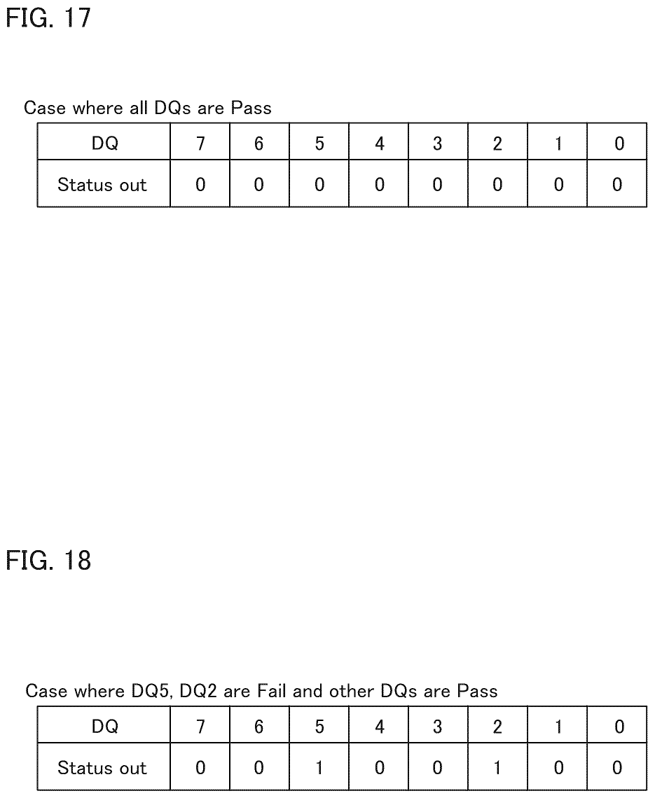

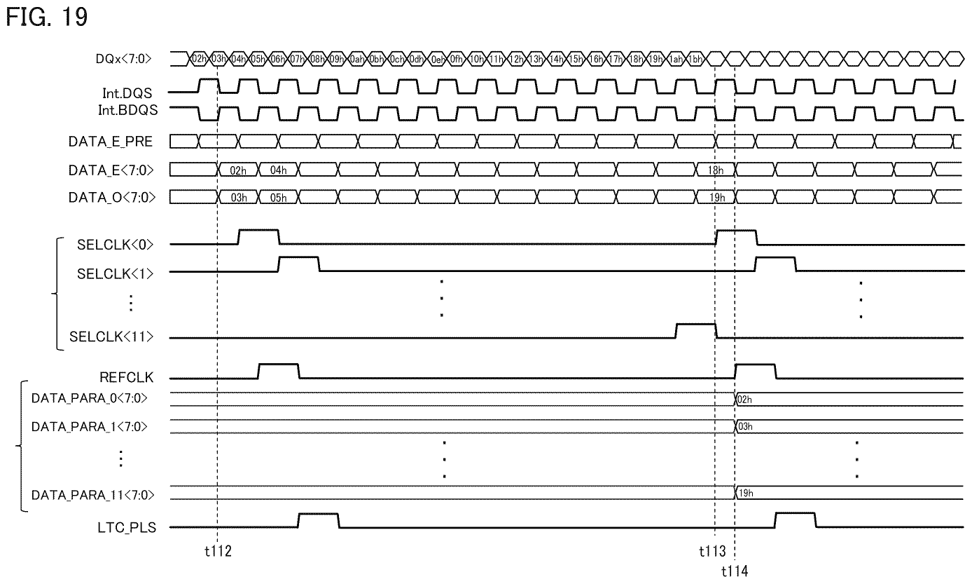

FIG. 16 is a schematic timing chart illustrating a state of the write data training operation. FIG. 17 is a drawing illustrating an exemplary result of a comparison performed in the data storage region 270 according to the first embodiment. FIG. 18 is a drawing illustrating an exemplary result of a comparison performed in the data storage region 270 according to the first embodiment. FIG. 19 is a schematic timing chart illustrating an exemplary expected value input method according to the first embodiment.

In the write data training operation, at time t₁₁₀, the command data “63h” and the address data “00h” are sequentially input from the controller die CD to the memory die MD via the data signal input/output terminals DQ0 to DQ7. That is, in a state where data “63h” (01100011) is set to the data signal input/output terminals DQ0 to DQ7, the signal of the control terminal CLE is set to “H”, and the signal of the control terminal ALE is set to “L”, the signal of the control terminal /CE is raised from “L” to “H”, and further, in a state where data “00h” (00000000) is set to the data signal input/output terminals DQ0 to DQ7, the signal of the control terminal CLE is set to “L”, and the signal of the control terminal ALE is set to “H”, the signal of the control terminal /CE is raised from “L” to “H”. The command data “63h” is the command data Cmd for the write data training operation. The address data “00h” includes the above-described LUN address.

After time t₁₁₁ after the command data “00h” is input, at a timing of rising edge or falling edge of the data strobe signal input to the data strobe signal input/output terminal DQS, the expected value data is input from the controller die CD to the memory die MD via the data signal input/output terminals DQ <7:0>. At this timing, since the signal COMP_EN is “L”, the pulse signals (signals LTC_IN_A <3:0>) are sequentially output from only the AND circuits 2702a <3:0> among the AND circuits 2702a, 2702b (FIG. 15B). Therefore, the expected value data is retrieved in the expected value latch region 272. In this embodiment, the expected value data may include information of 8×48 (=384) bits.

Next, at time t₂₁₀, the command data “63h” and the address data “00h” are sequentially input from the controller die CD to the memory die MD via the data signal input/output terminals DQ0 to DQ7.

After time t₂₁₂ after the command data “00h” is input, at a timing of rising edge or falling edge of the data strobe signal input to the data strobe signal input/output terminal DQS, the test data is input from the controller die CD to the memory die MD via the data signal input/output terminals DQ <7:0>. At this timing, since the signal COMP_EN is “H”, the pulse signals (signals LTC_IN_B <3:0>)are sequentially output from only the AND circuits 2702b <3:0> among the AND circuits 2702a, 2702b (FIG. 15B). Therefore, the expected value data is retrieved in the input data latch region 273. In this embodiment, the test data may include information of 8×48 (=384) bits.

When the test data is input, the latch enable signal is input to the latch circuits in the circuit elements 2742 (0) to 2742 (7), and the comparison result between the data in the expected value latch region 272 and the data in the input data latch region 273 is output to the sequencer SQC as the signals COMP <7:0>. When the test data is input multiple times between time t₂₁₂ and time t₃₁₀, the latch enable signal is input every time the data input is completed, and the signals COMP <7:0> are updated. The sequencer SQC stores the signals COMP <7:0> in the status register STR as the status data Stt.

Next, at time t₃₁₀, the command data “7xh” and address data “xxh” are sequentially input from the controller die CD to the memory die MD via the data signal input/output terminals DQ0 to DQ7. The command data “7xh” is the command data Cmd that instructs the status-read.

Next, at time t₃₁₁, when the signal input to the control terminal RE is fallen to “L”, the status register STR outputs the signals COMP <7:0> as the status data Stt.

The controller die CD can perform Pass/Fail determination using the acquired comparison result. FIG. 17 and FIG. 18 illustrate the comparison result acquired by the status-read. When the data input via the data signal input/output terminals DQ0 to DQ7 and the expected value data are same, “0” that means Pass is indicated, and when the data input via the data signal input/output terminals DQ0 to DQ7 and the expected value data are different, “1” that means Fail is indicated. FIG. 17 indicates that all the data input via the data signal input/output terminals DQ0 to DQ7 is same as the expected value data. Meanwhile, FIG. 18 indicates that the error has occurred in the data input via the data signal input/output terminals DQ2, DQ5 among the data input via the data signal input/output terminals DQ0 to DQ7.

FIG. 19 illustrates an exemplary operation of the parallel conversion circuit 260 in time period T_{exd} of FIG. 16.

In the example illustrated in the drawing, from time t112 to time t113, the data of 8×12 (=96) bits input to the data signal input/output terminals DQ0 to DQ7 over 12 cycles is retrieved in the latch circuits 261 (0) <7:0> to 261 (11) <7:0>.

For example, in the example illustrated in the drawing, since 02h is input to the data signal input/output terminals DQ0 to DQ7, and Int.DQS, Int.BDQS are switched in this state, the data DATA_E_PRE <7:0> (FIG. 11) is 02h. Next, since 03h is input to the data signal input/output terminals DQ0 to DQ7, and Int.DQS, Int.BDQS are switched in this state, the even number data DATA_E <7:0> is 02h and the odd number data DATA_O <7:0> is 03h.

Next, since 04h is input to the data signal input/output terminals DQ0 to DQ7, and Int.DQS, Int.BDQS are switched in this state, the data DATA_E_PRE <7:0> (FIG. 11) is 04h. Next, since 05h is input to the data signal input/output terminals DQ0 to DQ7, and Int.DQS, Int.BDQS are switched in this state, the even number data DATA_E <7:0> is 04h and the odd number data DATA_O <7:0> is 05h.

The signal SELCLK <0> rises at a timing after the switch of the even number data DATA_E <7:0> to 02h and the odd number data DATA_O <7:0> to 03h and before the switch of the even number data DATA_E <7:0> to 04h and the odd number data DATA_O <7:0> to 05h, and this causes the latch circuits 261 (0) <7:0> (FIG. 14) to retrieve 02h and causes the latch circuits 261 (1) <7:0> (FIG. 14) to retrieve 03h.

Similarly, the signal SELCLK <1> rises at a timing after the switch of the even number data DATA_E <7:0> to 04h and the odd number data DATA_O <7:0> to 05h and before the switch of the even number data DATA_E <7:0> to 06h and the odd number data DATA_O <7:0> to 07h, and this causes the latch circuits 261 (2) <7:0> (FIG. 14) to retrieve 04h and causes the latch circuits 261 (3) <7:0> (FIG. 14) to retrieve 05h.

In the following operation, similarly, 06h to 17h are retrieved in the latch circuits 261 (4) <7:0> to 261 (11) <7:0>.

Next, when the signal REFCLK rises at time t114, the data of the latch circuits 261 (0) <7:0> to 261 (11) <7:0> are retrieved in the latch circuits 262 (0) <7:0> to 262 (11) <7:0>, and the data DATA_PARA_0 <7:0> to the data DATA_PARA_11 <7:0> are switched.

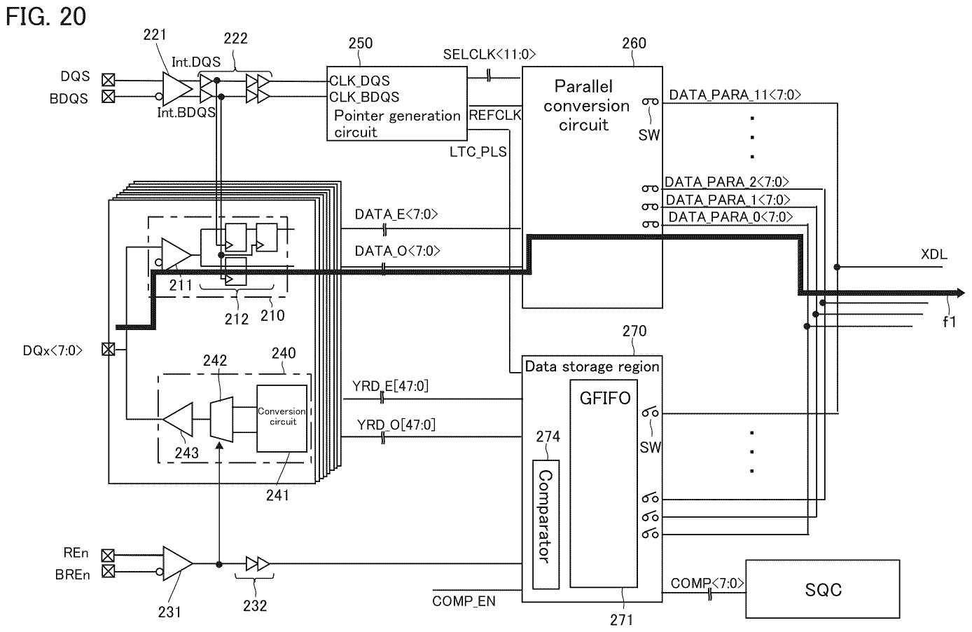

FIG. 20 to FIG. 22 are schematic circuit diagrams illustrating an exemplary configuration of the input/output control circuit I/O. FIG. 20 illustrates a data flow f1 in the data-in. FIG. 21 illustrates a data flow f2 in the data-out. FIG. 22 illustrates a data flow f3 in the write data training operation according to the first embodiment.

In the data-in, as illustrated in FIG. 20, for example, the-8 bit data is input via the data signal input/output terminals DQ <7:0>, and the 16-bit data is output from the input circuit 210 and input to the parallel conversion circuit 260. The parallel conversion circuit 260 outputs the 96-bit data. This data is output to the latch circuit XDL via the bus wiring DB. The switch SW of the data storage region 270 is OFF, and the data input to the data storage region 270 is not performed.

In the data-out, as illustrated in FIG. 21, the 96-bit data output from the latch circuit XDL is latched by the data latch unit GFIFO of the data storage region 270. The data latch unit GFIFO outputs the 96-bit data among the accumulated data to the output circuit 240. The output circuit 240 outputs the 8-bit data via the data signal input/output terminals DQ <7:0>. The switch SW of the parallel conversion circuit 260 is OFF, and the data output from the parallel conversion circuit 260 is not performed.

In the write data training operation according to the first embodiment, as illustrated in FIG. 22, the data input via the data signal input/output terminals DQ <7:0> is input to the data storage region 270 via the parallel conversion circuit 260. As described with reference to FIG. 16, the expected value data is input to the expected value latch region 272, and the test data is input to the input data latch region 273. As described with reference to FIG. 16, in the write data training operation, the comparator 274 compares the data in the expected value latch region 272 with the data in the input data latch region 273, and outputs the comparison result to the sequencer SQC as the signals COMP <7:0>. The sequencer SQC stores the signals COMP <7:0> received from the comparator 274 of the data storage region 270 in the status register STR as the status data Stt.

### Other Data Training Operations

The data training operation of the semiconductor memory device according to the first embodiment is described above. However, the data training operation described above is only an example, and the data training operation can be executed in various aspects.

### Example of Applying Write Data Training Operation to SCA

In the above description, the command data and the address data of the write data training operation are input via the data signal input/output terminals DQ0 to DQ7. However, the command data and the address data in the write data training operation according to the embodiment may be input via the control terminal ALE or the control terminal CLE. An operation mode allowing the input of the command data and the address data via the control terminal ALE or the control terminal CLE different from that of the data signal input/output terminals DQ0 to DQ7 is referred to as Separate Command Address input (SCA) in some cases.

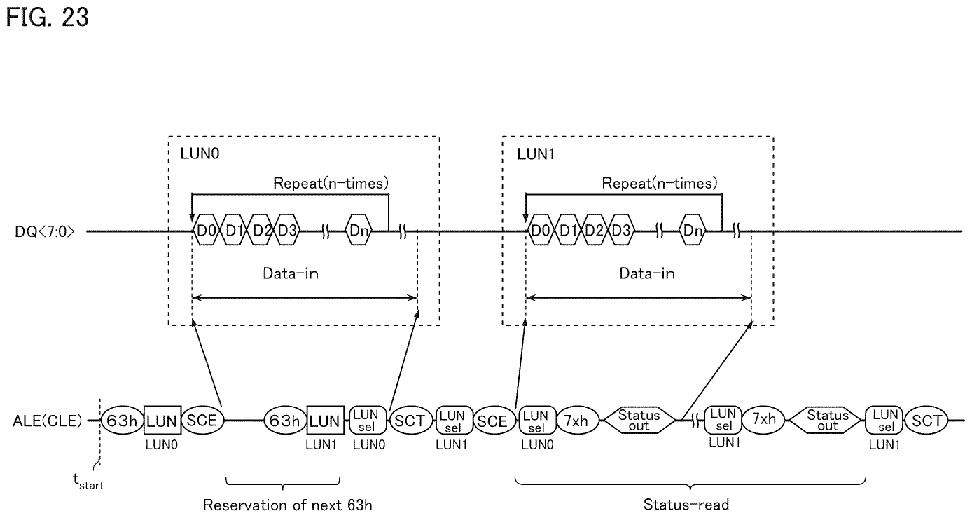

FIG. 23 is a schematic timing chart in a case where the write data training operation according to the embodiment is applied to SCA.

In this modification, as illustrated in FIG. 23, at the start of the write data training operation (time tₛₜₐᵣₜ), the command data “63h”, the LUN address “LUN” specifying LUN0, and command data “SCE” are sequentially input from the controller die CD to the memory die MD via the control terminals CLE, ALE. The command data “SCE” is an abbreviation of “Select Chip Enable”, and input at a timing of starting the data input or the data output.

After the command data “SCE” is input, as illustrated in FIG. 23, the same data as the expected value data for is input from the controller die CD to the memory die MD assigned to LUN0 via the data signal input/output terminals DQ <7:0>. Thus, the data-in of inputting the test data (data in which data patterns (data D0 to Dn) having a predetermined bit length are repeated n times) to the memory die MD assigned to LUN0 via the data signal input/output terminals DQ0 to DQ7 is executed.

After the command data “SCE” is input, the command data “63h” and the LUN address “LUN” specifying LUN1 are sequentially input from the controller die CD to the memory die MD via the control terminals CLE, ALE.

After the LUN address “LUN” specifying LUN1 is input, command data “LUN SEL” and command data “SCT” are sequentially input from the controller die CD to the memory die MD via the control terminals CLE, ALE. The command data “LUN SEL” identifies the memory die MD (here, the memory die MD assigned to LUN0) as a target of the next command data (here, the command data “SCT”). The command data “SCT” is an abbreviation of “Select Chip Terminate”, and input at a timing of ending the data input or the data output. Thus, the data input to the memory die MD assigned to LUN0 is completed.

After the command data “SCT” is input, the command data “LUN SEL” and the command data “SCE” are input from the controller die CD to the memory die MD via the control terminals CLE, ALE. The command data “LUN SEL” here identifies and selects the memory die MD (here, the memory die MD assigned to LUN1) as a target of the next command data (here, the command data “SCE”). Thus, the memory die MD assigned to LUN1 is selected.

After the command data “SCE” is input, as illustrated in FIG. 23, the same data as the expected value data for the memory die MD is input from the controller die CD to the memory die MD assigned to LUN1 via the data signal input/output terminals DQ <7:0>. Thus, the data-in of inputting the test data (data in which data patterns (data D0 to Dn) having a predetermined bit length are repeated n times) to the memory die MD assigned to LUN1 via the data signal input/output terminals DQ0 to DQ7 is executed.

After the command data “SCE” is input, the command data “LUN SEL” and the command data “7xh” are input from the controller die CD to the memory die MD via the control terminals CLE, ALE. The command data “LUN SEL” here identifies the memory die MD (here, the memory die MD assigned to LUN0) that the next command data (here, the command data “7xh”) accesses.

After the command data “7xh” is input, for example, the status-read of the memory die MD assigned to LUN0 is executed. When the status-read is executed, the comparison result between the data input to the memory die MD assigned to LUN0 and the expected value latched in the memory die MD assigned to LUN0 is output as the status data Stt via the control terminals CLE, ALE.

Since the status-read of the memory die MD assigned to LUN0 is performed without the data signal input/output terminals DQ0 to DQ7, the status-read of the memory die MD assigned to LUN0 can be performed in the background of the data-in (in parallel to the data-in) performed on the memory die MD assigned to LUN1.

After the write data training operation of the memory die MD assigned to LUN0, the command data “LUN SEL” and the command data “7xh” are input from the controller die CD to the memory die MD via the control terminals CLE, ALE. The command data “LUN SEL” here identifies the memory die MD (here, the memory die MD assigned to LUN1) that the next command data (here, the command data “7xh”) accesses.

After the command data “7xh” is input, for example, the status-read of the memory die MD assigned to LUN1 is executed. When the status-read is executed, the comparison result between the data input to the memory die MD assigned to LUN1 and the expected value latched in the memory die MD assigned to LUN1 is output as the status data Stt via the control terminals CLE, ALE.

When the write data training operation according to the embodiment is applied to SCA, the input of the command data and the acquisition of the status data Stt can be executed in the background of the data-in, and therefore, the time overhead caused by the write data training operation can be further reduced.

### Example of Simultaneously Executing Write Data Training Operation on a Plurality of Memory Dies MD

In the above description, an example in which the memory die MD is selected one by one and the test data (data in which data patterns (data D0 to Dn) having the predetermined bit length are repeated n times) is input each time when the write data training operation is executed on a plurality of memory dies MD is described. However, the write data training operation of a plurality of memory dies MD can be simultaneously executed.

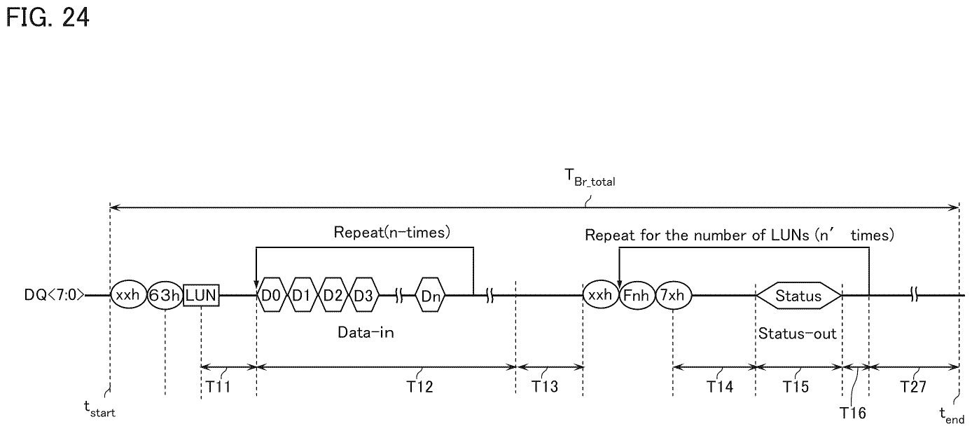

FIG. 24 is a schematic timing chart in a case where the write data training operation is simultaneously executed on a plurality of memory dies MD.

The write data training operation illustrated in FIG. 24 is basically executed similarly to the write data training operation described with reference to FIG. 9.

However, in the example of FIG. 24, at the start of the write data training operation (time tₛₜₐᵣₜ), the command data “xxh” is input before the command data “63h”. The command data “xxh” here is the command data Cmd that instructs to select the memory dies MD corresponding to all LUNs (here, two of LUN0 and LUN1).

Thus, in time period T12, the write data training operation is simultaneously executed on all the memory dies MD.

In the example of FIG. 24, after the execution of the write data training operation, the command data “xxh” is input from the controller die CD to the memory die MD via the data signal input/output terminals DQ0 to DQ7. The command data “xxh” here is the command data Cmd that instructs to release the selection of all LUNs (here, two of LUN0 and LUN1).

In the example of FIG. 24, after the input of the command data “xxh”, command data “Fnh” and the command data “7xh” are sequentially input from the controller die CD to the memory die MD via the data signal input/output terminals DQ0 to DQ7. The command data “Fnh” here is the command data Cmd for selecting the memory die MD.

After the command data “7xh” is input, the status-read of the selected memory die MD is executed. When the status-read is executed, the comparison result between the data input to the memory die MD and the expected value latched in the memory die MD is output as the status data Stt.

The input of the command data “Fnh”, “7xh” and the output of the status data Stt are executed separately for all the memory dies MD.

After the execution of the status-read of the memory die MD for the number of LUNs (n′ times), in time period T27, the controller die CD performs the Skew adjustment of the data strobe signal input to the data strobe signal input/output terminal DQS and the data input to the data signal input/output terminals DQ <7:0> and the adjustment of the reference voltage VREF of the memory die MD according to the comparison result of the status-read.

### Second Embodiment

In the first embodiment, an example in which the expected value data is input from the controller die CD to the memory die MD in the write data training operation is described. However, such an operation is only an example, and specific method and the like can be adjusted as appropriate. For example, the expected value data may be latched inside the memory die MD, or may be generated inside the memory die MD.

In the second embodiment, an example in which a Pseudo-Random Binary Sequence (PRBS) generation circuit is provided inside the memory die MD, and the expected value data is generated inside the memory die MD using the PRBS generation circuit is described.

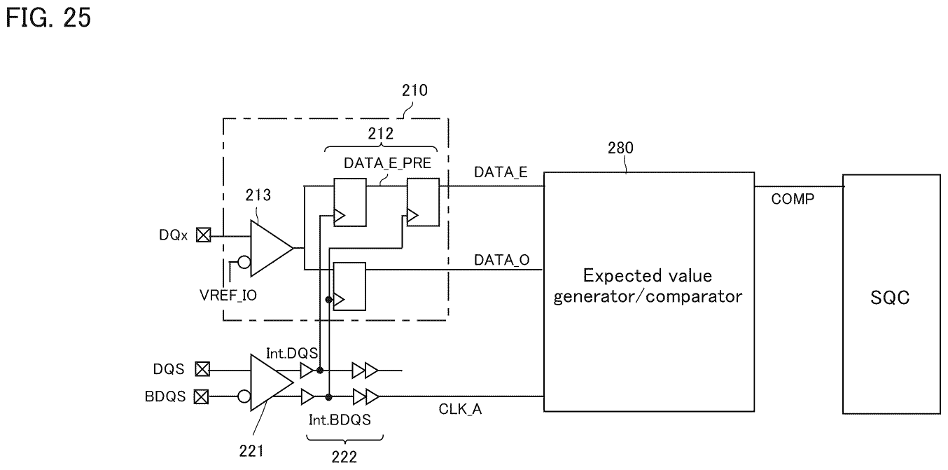

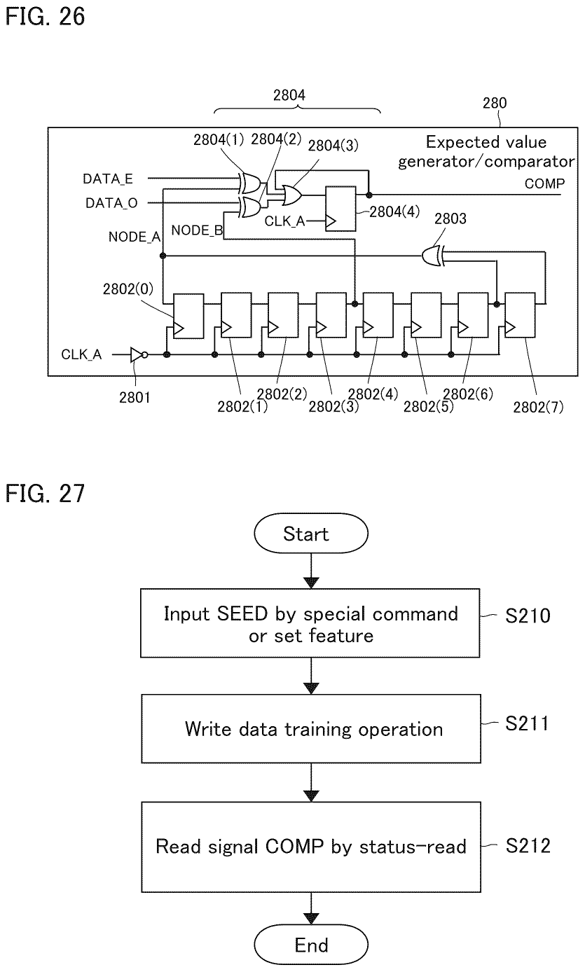

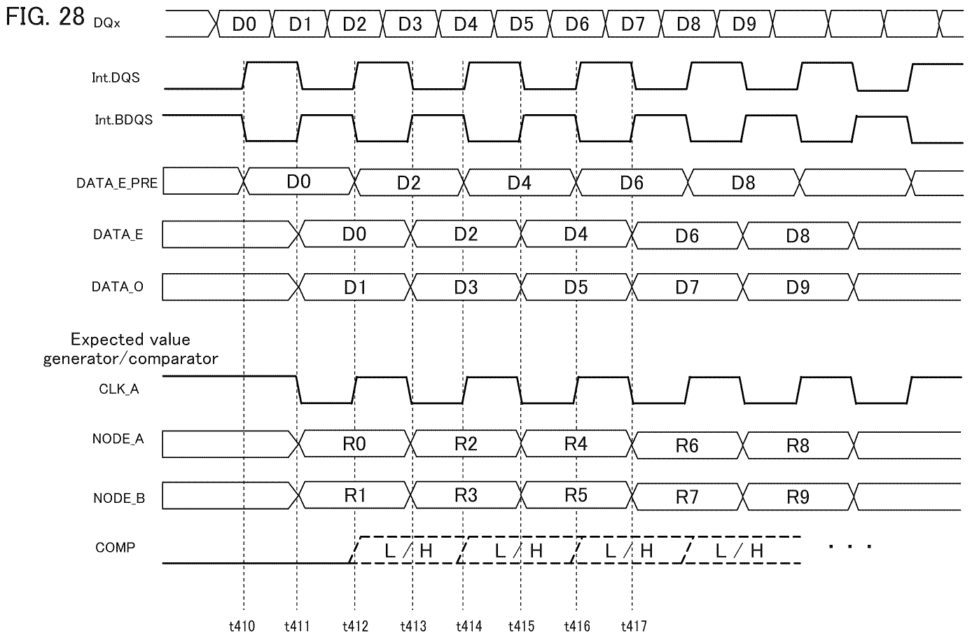

FIG. 25 is a schematic circuit diagram illustrating a configuration of a part of an input/output control circuit I/O according to the second embodiment. FIG. 26 is a schematic circuit diagram illustrating a configuration of an expected value generator/comparator 280 according to the second embodiment. FIG. 27 is a flowchart illustrating an exemplary write data training operation of the input/output control circuit I/O according to the second embodiment. FIG. 28 is a schematic timing chart illustrating a part of the write data training operation of the input/output control circuit I/O according to the second embodiment. FIG. 28 illustrates an operation of the expected value generator/comparator 280.

The input/output control circuit I/O according to the second embodiment is basically configured similarly to the input/output control circuit I/O according to the first embodiment. However, the input/output control circuit I/O according to the second embodiment includes, for example, as illustrated in FIG. 25, the expected value generator/comparator 280.

The expected value generator/comparator 280 is a circuit for generating data patterns (data D0 to Dn) that are to be expected value data and have a predetermined bit length and comparing the data patterns with the data patterns (data D0 to Dn) that are input to the input circuit 210, have the predetermined bit length, and are repeated n times. As illustrated in FIG. 26, the expected value generator/comparator 280 includes a NOT circuit 2801, a plurality of latch circuits 2802 (0) to 2802 (7), an XOR circuit 2803, and a comparator 2804.

The NOT circuit 2801 receives a signal CLK_A that is an output signal of the comparator 221 (FIG. 25). The NOT circuit 2801 has an output terminal connected to the latch circuits 2802 (0) to 2802 (7). An output signal of the NOT circuit 2801 is input to the latch circuits 2802 (0) to 2802 (7) as the latch enable signal.

The plurality of latch circuits 2802 (0) to 2802 (7) and the XOR circuit 2803 constitute the PRBS generation circuit. The PRBS generation circuit has an initial value (seed) that can be input from outside by a special command or set feature to the memory die MD. The latch circuit 2802 (0) in the first stage receives an output of the XOR circuit 2803 by feedback input. An output of the latch circuit 2802 (4) in the fourth stage is output to the comparator 2804 as expected value data NODE_B. An output of the latch circuit 2802 (6) in the seventh stage and an output of the latch circuit 2802 (7) in the eighth stage are input to the XOR circuit 2803. An output of the XOR circuit 2803 is output to the comparator 2804 as expected value data NODE_A.

While the input terminal of the latch circuit 2802 (0) in the first stage and the output terminal of the latch circuit 2802 (4) in the fourth stage are connected to the comparator 2804 in the example of FIG. 26, such a configuration can be adjusted as appropriate. For example, it is only necessary that the input terminal and the output terminal of any of the latch circuits 2802 (0) to 2802 (7) are connected to the comparator 2804 according to the rule of the data patterns (data D0 to Dn) input from the input circuit 210 and having the predetermined bit length.

While the PRBS generation circuit illustrated in FIG. 26 includes the plurality of latch circuits 2802 (0) to 2802 (7) and the XOR circuit 2803, such a configuration also can be adjusted as appropriate. Any configuration may be employed insofar as the data patterns (data D0 to Dn) having the predetermined bit length can be formed with a pseudo-random signal.

The comparator 2804 includes an XOR circuit 2804 (1), an XOR circuit 2804 (2), an OR circuit 2804 (3), and a latch circuit 2804 (4). The XOR circuit 2804 (1) receives the data DATA_E and the output of the XOR circuit 2803. The XOR circuit 2804 (2) receives the data DATA_O and the output of the latch circuit 2802 (3). The OR circuit 2804 (3) is a three-input OR circuit, and receives the output of the XOR circuit 2804 (1), the output of the XOR circuit 2804 (2), and the output of the latch circuit 2804 (4). The latch circuit 2804 (4) receives the signal CLK_A as the latch enable signal, receives the output of the OR circuit 2804 (3) as the input signal, and outputs the signal COMP indicating the comparison result between the expected value data and the input data. In this configuration, when the expected value data is different from the input data, the output signal of the OR circuit 2804 (3) becomes the “H” state, and the latch circuit 2804 (4) latches this output signal in the “H” state. After this, the signal COMP is fixed to “H”.

Subsequently, the operation of the input/output control circuit I/O according to the second embodiment is described. For example, as illustrated in FIG. 27, the controller die CD inputs the initial value (seed) by the special command or set feature before the execution of the write data training operation (S210). Next, the controller die CD executes the write data training operation (S211). Next, the controller die CD executes the status-read to read the signal COMP indicating the comparison result (S212).

Subsequently, with reference to FIG. 28, the write data training operation according to the embodiment is described.

In the example illustrated in the drawing, since D0h is input to the data signal input/output terminals DQ0 to DQ7 at time t410, and Int.DQS, Int.BDQS are switched in this state, the data DATA_E_PRE <7:0> (FIG. 11) is D0h.

Next, since D1h is input to the data signal input/output terminals DQ0 to DQ7 at time t411, and Int.DQS, Int.BDQS are switched in this state, the even number data DATA_E <7:0> is D0h and the odd number data DATA_O <7:0> is D1h. The signal CLK_A falls, and the PRBS generation circuit outputs data R0 as the expected value data NODE_A and data R1 as the expected value data NODE_B.

Next, since D2h is input to the data signal input/output terminals DQ0 to DQ7 at time t412, and Int.DQS, Int.BDQS are switched in this state, the data DATA_E_PRE <7:0> (FIG. 11) is D2h. The signal CLK_A rises, the output signal of the OR circuit 2804 (3) is latched in the latch circuit 2804 (4), and this signal is output as the signal COMP.

Next, since D3h is input to the data signal input/output terminals DQ0 to DQ7 at time t413, and Int.DQS, Int.BDQS are switched in this state, the even number data DATA_E <7:0> is D2h and the odd number data DATA_O <7:0> is D3h. The signal CLK_A falls, and the PRBS generation circuit outputs data R2 as the expected value data NODE_A and data R3 as the expected value data NODE_B.

In the following operation, similarly, while the input data to the data signal input/output terminals DQ0 to DQ7 is switched, Int.DQS, Int.BDQS are sequentially switched, thereby executing the write data training operation.

### Third Embodiment

The memory die MD according to the second embodiment includes the eight expected value generator/comparators 280 corresponding to the eight data signal input/output terminals DQ0 to DQ7. However, such a configuration is only an example, and specific configurations can be adjusted as appropriate. For example, one expected value generator/comparator 280 can be used for two or more data signal input/output terminals DQ. This allows restraining the increase in the circuit area.

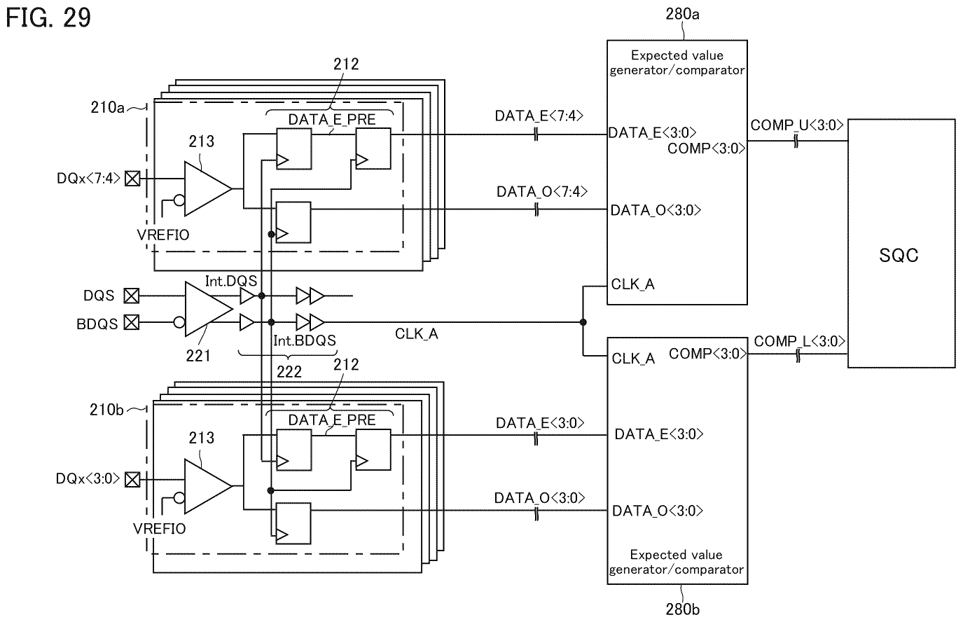

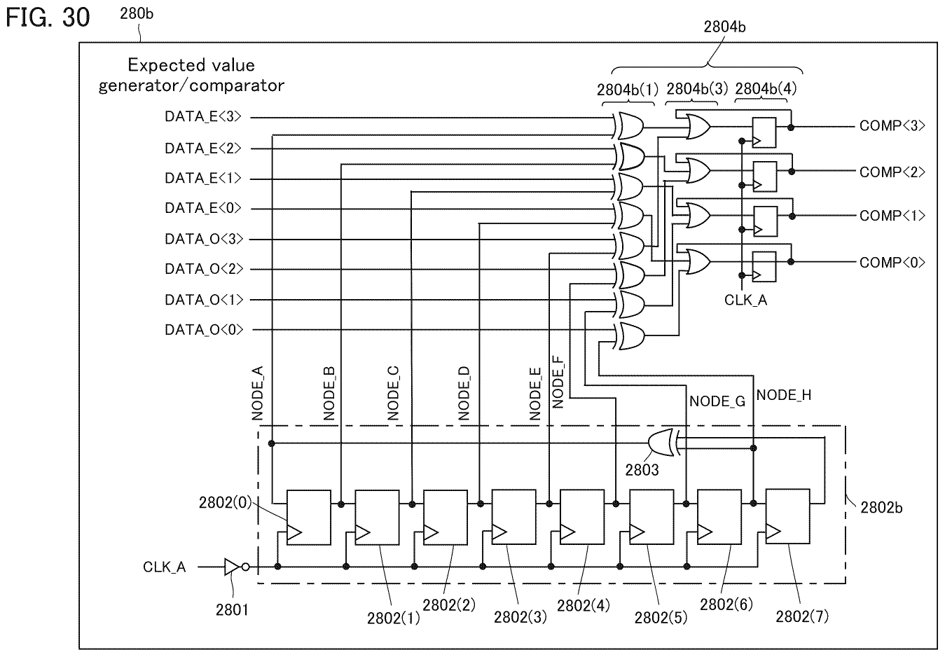

FIG. 29 is a schematic circuit diagram illustrating a configuration of a part of an input/output control circuit I/O according to the third embodiment. FIG. 30 is a schematic circuit diagram illustrating a configuration of an expected value generator/comparator 280b according to the third embodiment.

The input/output control circuit I/O according to the third embodiment is basically configured similarly to the input/output control circuit I/O according to the second embodiment. However, the input/output control circuit I/O according to the third embodiment includes, for example, as illustrated in FIG. 29, expected value generators/comparators 280a, 280b instead of the expected value generator/comparator 280.

The expected value generators/comparators 280a, 280b are basically configured similarly to the expected value generator/comparator 280 according to the second embodiment. However, the expected value generator/comparator 280a is disposed corresponding to the data signal input/output terminals DQ4 to DQ7, and receives data DATA_E <7:4> and data DATA_O <7:4> corresponding to the data signal input/output terminals DQ4 to DQ7. The expected value generator/comparator 280b is disposed corresponding to the data signal input/output terminals DQ0 to DQ3, and receives data DATA_E <3:0> and data DATA_O <3:0> corresponding to the data signal input/output terminals DQ0 to DQ3.

For example, as illustrated in FIG. 30, the expected value generator/comparator 280b includes the NOT circuit 2801, a PRBS generation circuit 2802b, and a comparator 2804b.

The PRBS generation circuit 2802b includes latch circuits 2802 (0) to 2802 (7) similarly to the expected value generator/comparator 280 according to the second embodiment. In this embodiment, the output of the XOR circuit 2803 is output to the comparator 2804b as the expected value data NODE_A, and the output of the latch circuit 2802 (0) in the first stage is output to the comparator 2804b as the expected value data NODE_B. The output of the latch circuit 2802 (1) in the second stage is output to the comparator 2804b as expected value data NODE_C, and the output of the latch circuit 2802 (2) in the third stage is output to the comparator 2804b as expected value data NODE_D. Similarly, the output of the latch circuit 2802 (3) in the fourth stage is output to the comparator 2804b as expected value data NODE_E, the output of the latch circuit 2802 (4) in the fifth stage is output to the comparator 2804b as expected value data NODE_F, the output of the latch circuit 2802 (5) in the sixth stage is output to the comparator 2804b as expected value data NODE_G, and the output of the latch circuit 2802 (6) in the seventh stage is output to the comparator 2804b as expected value data NODE_H.

The comparator 2804b includes a plurality of XOR circuits 2804b (1), a plurality of OR circuits 2804b (3), and a plurality of latch circuits 2804b (4).

In the example illustrated in the drawing, the eight XOR circuits 2804b (1) are disposed corresponding to 8-bit data DATA_E <3:0>, DATA_O <3:0>. The XOR circuit 2804b (1) receives any one bit of the 8-bit data DATA_E <3:0>, DATA_O <3:0>, and any one bit of the 8-bit data NODE_A to NODE_H.

The four OR circuits 2804b (3) are disposed corresponding to the four data signal input/output terminals DQ0 to DQ3. The OR circuit 2804b (3) is a three-input OR circuit, and receives the output of the XOR circuit 2804b (1) corresponding to any one of the 4-bit data DATA_E <3:0>, the output of the XOR circuit 2804b (1) corresponding to any one of the 4-bit data DATA_O <3:0>, and the output of the latch circuit 2804b (4).

The latch circuit 2804b (4) receives the signal CLK_A as the latch enable signal, receives the output of the OR circuit 2804b (3) as the input signal, and outputs the signal COMP <0> indicating the comparison result between the expected value data and the input data. This configuration allows the comparator 2804b to compare the expected value data with the test data for each DQ.

The configuration of the expected value generator/comparator 280a is approximately similar to the configuration of the expected value generator/comparator 280b, and therefore, the explanation is omitted.

When the output of the expected value generators/comparators 280a, 280b according to the third embodiment is further simplified, the signal COMP <3:0> and the signal COMP <7:4> output from the expected value generators/comparators 280a, 280b may be collectively latched in one bit.

### Fourth Embodiment

In the embodiments of the first embodiment to the third embodiment, in the write data training operation, the expected value data is compared with the test data to confirm whether or not the bit error has occurred at the data reception, and the propriety of Skew and the reference voltage of the input circuit 201 (FIG. 8) is confirmed based on the comparison result. However, such a method is only an example, and the specific method can be adjusted as appropriate.

In the write data training operation according to the fourth embodiment, a parity bit is added to the data input from the controller die CD to the memory die MD (input/output control circuit I/O), and the data with the parity bit is coded. After the input of the data, whether or not the error has occurred inside the memory die MD is computed. In the fourth embodiment, an example of adding a code indicating whether the number of “1” included in a bit string is even or odd to the data is described.

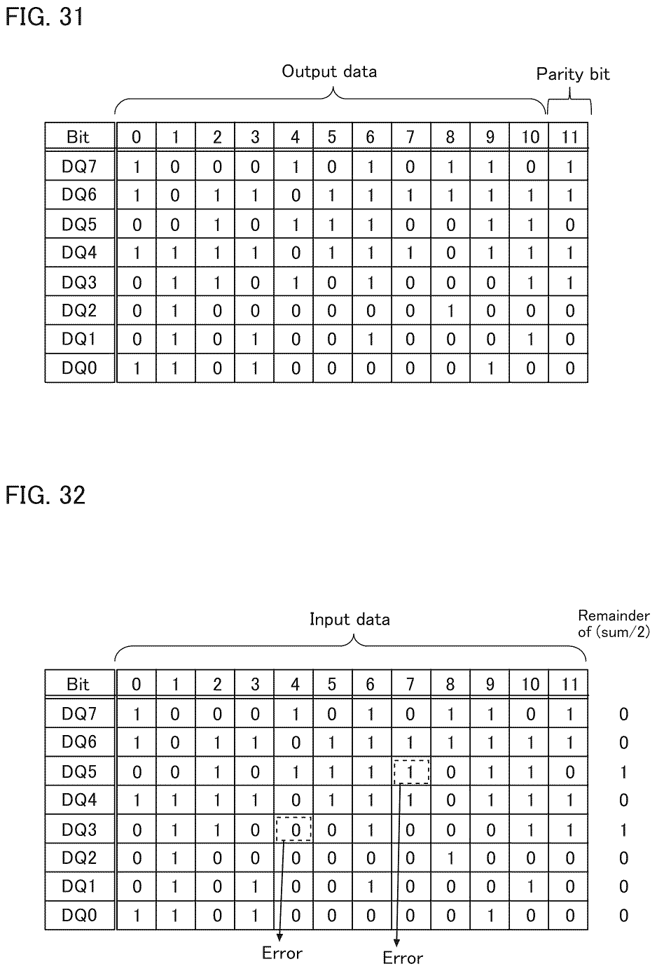

FIG. 31 and FIG. 32 are drawings for describing the write data training operation according to the fourth embodiment. In the example of FIG. 31, data of eight bits×11 cycles (=88 bits) is input from the controller die CD to the memory die MD, and 8-bit data for a parity check is input at the twelfth cycle. In the example illustrated in the drawing, for the eight data signal input/output terminals DQ0 to DQ7, a sum of the data input from the first cycle to the eleventh cycle is an even number, the parity bit input to the twelfth cycle is “0”, and when the sum is an odd number, the parity bit is “1”.

For example, in the example illustrated in the drawing, the 11-bit data input from the controller die CD to the data signal input/output terminal DQ0 is “1, 1, 0, 1, 0, 0, 0, 0, 0, 1, 0”, and the sum is 4 as an even number, therefore, the parity bit corresponding to the data signal input/output terminal DQ0 is “0”. Meanwhile, the 11-bit data input from the controller die CD to the data signal input/output terminal DQ3 is “0, 1, 1, 0, 1, 0, 1, 0, 0, 0, 1”, and the sum is 5 as an odd number, therefore, the parity bit corresponding to the data signal input/output terminal DQ3 is “1”.

Thus, each of the sums of the 12-bit data including the parity bit input to the data signal input/output terminals DQ0 to DQ7 over 12 cycles become an even number. Therefore, for example, the sum of one of these pieces of the 12-bit data is divided by 2, and when the remainder is 1, it is confirmed that the error has occurred anywhere in the 12-bit data input to the memory die MD (input/output control circuit I/O).

For example, in the example of FIG. 32, in the 12-bit data input to the data signal input/output terminal DQ3, the data input in the fifth cycle is the error. Therefore, when the sum of the 12-bit data is divided by 2, the remainder is 1, and the occurrence of error is found.

Subsequently, the configuration of the input/output control circuit I/O to achieve the write data training operation according to the embodiment is described.

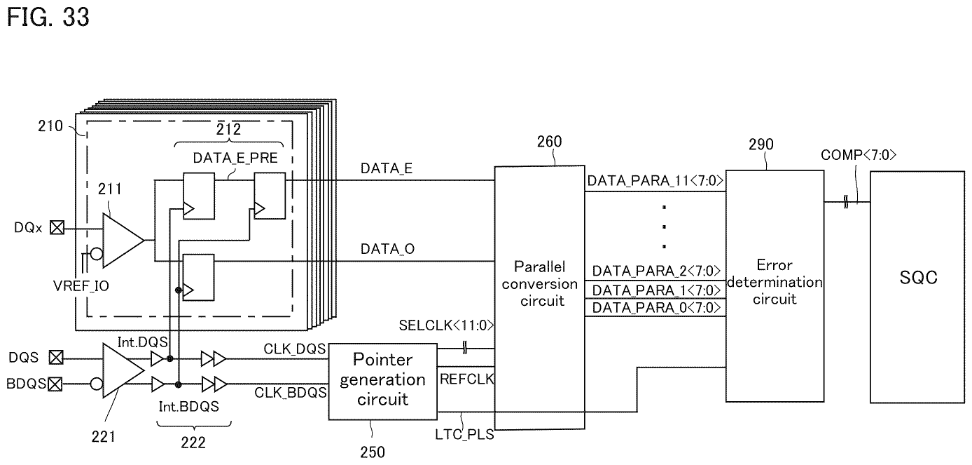

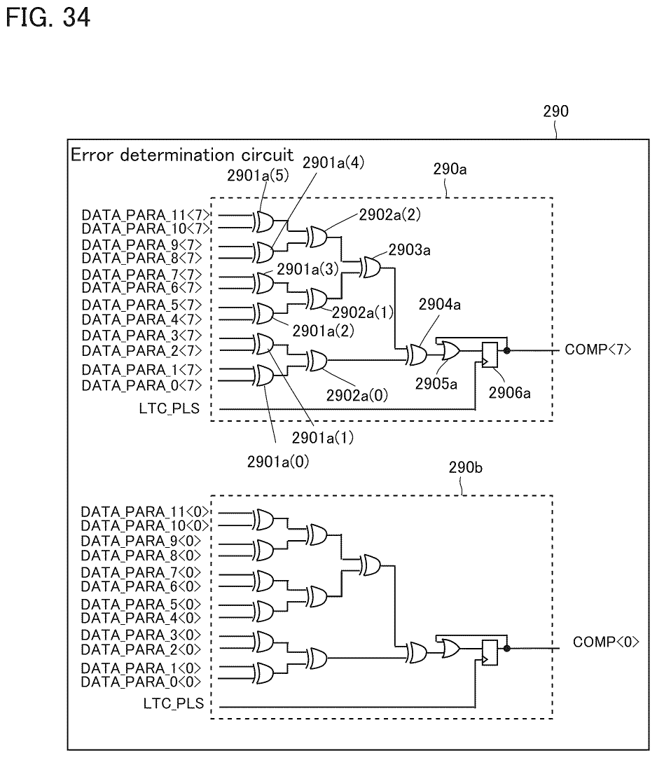

FIG. 33 is a schematic circuit diagram illustrating a configuration of a part of the input/output control circuit I/O according to the fourth embodiment. FIG. 34 is a schematic circuit diagram illustrating a configuration of an error determination circuit 290 according to the fourth embodiment.

The input/output control circuit I/O (FIG. 2) according to the fourth embodiment is basically configured similarly to the input/output control circuit I/O according to the first embodiment. However, the input/output control circuit I/O according to the fourth embodiment includes, for example, as illustrated in FIG. 33, the error determination circuit 290.

The error determination circuit 290 includes eight determination circuits corresponding to the eight data signal input/output terminals DQ0 to DQ7. FIG. 34 illustrates a determination circuit 290a corresponding to the data signal input/output terminal DQ7 and a determination circuit 290b corresponding to the data signal input/output terminal DQ0 among these eight determination circuits.

The determination circuit 290a includes XOR circuits 2901a (0) to 2901a (5), 2902a (0) to 2902a (2), 2903a, 2904a, an OR circuit 2905a, and a latch circuit 2906a.

The XOR circuit 2901a (0) has one input terminal to which the data DATA_PARA_0 <7> is input, and the other input terminal to which the data DATA_PARA_1 <7> is input. The XOR circuit 2901a (1) has one input terminal to which the data DATA_PARA_2 <7> is input, and the other input terminal to which the data DATA_PARA_3 <7> is input. The XOR circuit 2901a (2 )has one input terminal to which the data DATA_PARA_4 <7> is input, and the other input terminal to which the data DATA_PARA_5 <7> is input. The XOR circuit 2901a (3) has one input terminal to which the data DATA_PARA_6 <7> is input, and the other input terminal to which the data DATA_PARA_7 <7> is input. The XOR circuit 2901a (4) has one input terminal to which the data DATA_PARA_8 <7> is input, and the other input terminal to which the data DATA_PARA_9 <7> is input. The XOR circuit 2901a (5) has one input terminal to which the data DATA_PARA_10 <7> is input, and the other input terminal to which the data DATA_PARA_11 <7> is input.

The XOR circuit 2902a (0) has one input terminal to which the output of the XOR circuit 2901a (0) is input, and the other input terminal to which the output of the XOR circuit 2901a (1) is input. The XOR circuit 2902a (1) has one input terminal to which the output of the XOR circuit 2901a (2 ) is input, and the other input terminal to which the output of the XOR circuit 2901a (3) is input. The XOR circuit 2902a (2 ) has one input terminal to which the output of the XOR circuit 2901a (4) is input, and the other input terminal to which the output of the XOR circuit 2901a (5) is input.

The XOR circuit 2903a has one input terminal to which the output of the XOR circuit 2902a (1) is input, and the other input terminal to which the output of the XOR circuit 2902a (2 ) is input. The XOR circuit 2904a has one input terminal to which the output of the XOR circuit 2902a (0) is input, and the other input terminal to which the output of the XOR circuit 2903a is input.

The OR circuit 2905a has one input terminal to which the output of the XOR circuit 2904a is input, and the other input terminal to which the output of the latch circuit 2906a is input. The latch circuit 2906a receives the signal LTC_PLS (clock signal) as the latch enable signal, receives the output of the OR circuit 2905a as the input signal, and outputs the signal COMP <7> to the sequencer SQC as the output signal.

With this configuration, the determination circuit 290a outputs “0” as the signal COMP when the sum of the data DATA_PARA_0 <7> to the data DATA_PARA_11 <7> is an even number, and outputs “1” as the signal COMP when the sum is an odd number. The determination circuit 290a can repeatedly perform the error determination, for example, in a unit of 12 bits. The determination circuit 290a fixes the signal COMP to “1” when the error is determined even once.

The seven determination circuits corresponding to the other seven data signal input/output terminals DQ0 to DQ6 in the error determination circuit 290 are configured similarly to the determination circuit 290a. Therefore, the explanation of these seven determination circuits is omitted.

### Fifth Embodiment

As described above, the expected value data may be preliminarily latched inside the memory die MD. Such an example is described below as a write data training operation according to the fifth embodiment. In the fifth embodiment, a plurality of pieces of the expected value data are preliminarily latched in the memory die MD. In the write data training operation, the expected value data is selected according to the address signal.

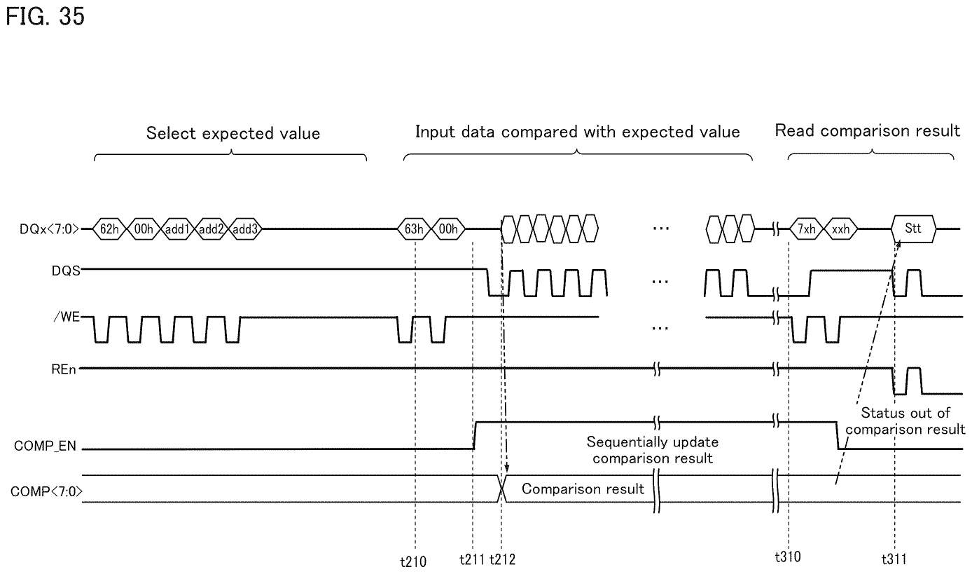

FIG. 35 is a schematic timing chart illustrating a state of the write data training operation according to the fifth embodiment.

The write data training operation according to the fifth embodiment is basically executed similarly to the write data training operation according to the first embodiment.

However, as described with reference to FIG. 16, in the write data training operation according to the first embodiment, the command data “63h”, the address data “LUN”, and the expected value data are input from the controller die CD to the memory die MD.

Meanwhile, as illustrated in FIG. 35, in the write data training operation according to the fifth embodiment, the command data “62h”, the address data “LUN”, and address data “add1”, “add2”, “add3” are input from the controller die CD to the memory die MD, thereby selecting one of the plurality of pieces of the expected value data latched in the memory die MD. The address data “add1”, “add2”, “add3” are data for selecting one piece of the expected value data from the plurality of pieces of the expected value data.

In the example of FIG. 16, the data strobe signal input/output terminals DQS, /DQS are used at the input of the expected value data. Meanwhile, in the example of FIG. 35, since the expected value data is not input, the data strobe signal input/output terminals DQS, /DQS are not used.

### Other Embodiments

The semiconductor memory devices according to the first embodiment to the fifth embodiment are described above. However, the above descriptions are only examples, and the specific configuration and the like can be adjusted as appropriate.

For example, as described with reference to FIG. 23, the write data training operation according to the first embodiment is applicable to SCA. The write data training operation according to the second embodiment to the fifth embodiment is similarly applicable to SCA.

For example, as described with reference to FIG. 24, in the first embodiment, the write data training operation can be executed simultaneously on a plurality of memory dies MD. In the write data training operation according to the second embodiment to the fifth embodiment, similarly, the write data training operation can be executed simultaneously on a plurality of memory dies MD.

### Others

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor memory device comprising:
a memory cell array;
a first pad electrode that receives write data at an input of the write data to be written in the memory cell array and outputs read data at an output of the read data read from the memory cell array;
a first comparator having one input terminal connected to the first pad electrode and the other input terminal to which a reference voltage is applied;
a first latch circuit that latches an output signal of the first comparator corresponding to a first latch enable signal; and
a second pad electrode to which the first latch enable signal is supplied at the input of the write data, wherein
the semiconductor memory device is configured to be able to perform a write data training operation at an adjustment of a time interval between a timing of inputting the write data to the first pad electrode and a timing of inputting the first latch enable signal to the second pad electrode, and at an adjustment of the reference voltage,
the semiconductor memory device receives a plurality of bits of test data via the first pad electrode, and generates data indicating whether or not a bit error has occurred at the input of the test data in the write data training operation, and
the semiconductor memory device is configured to be able to output the data indicating whether or not the bit error has occurred.

2. The semiconductor memory device according to claim 1, wherein
in the write data training operation,
expected value data is input,
the test data that matches the expected value data is input once or multiple times, and
respective bits of the expected value data are compared with respective bits of the input test data.

3. The semiconductor memory device according to claim 2, further comprising:
a parallel conversion circuit that performs a serial-to-parallel conversion of the write data output from the first latch circuit, and outputs the converted data to the memory cell array via a data bus at the input of the write data;
a plurality of second latch circuits that latch signals of respective bits of the data bus corresponding to a second latch enable signal at the output of the read data;
a first signal generation circuit that outputs the second latch enable signal to only a part of the plurality of second latch circuits at the input of the expected value data;
a second signal generation circuit that outputs the second latch enable signal to only another part of the plurality of second latch circuits at the input of the test data; and
a comparator that compares data of the part of the plurality of second latch circuits with data of the another part of the plurality of second latch circuits.

4. The semiconductor memory device according to claim 3, wherein
the comparator includes:
a plurality of exclusive OR output circuits each having one input terminal connected to one of the part of the plurality of second latch circuits and the other input terminal connected to one of the another part of the plurality of second latch circuits;
an OR output circuit that receives output signals of the plurality of exclusive OR output circuits and the data indicating whether or not the bit error has occurred, and outputs a logical disjunction; and
a third latch circuit that latches an output signal of the OR output circuit, and outputs the latched signal as the data indicating whether or not the bit error has occurred.

5. The semiconductor memory device according to claim 1, further comprising
an expected value generator/comparator that generates expected value data, wherein
in the write data training operation,
the test data that matches the expected value data is input once or multiple times, and
respective bits of the expected value data are compared with respective bits of the input test data.

6. The semiconductor memory device according to claim 5, wherein
the expected value generator/comparator includes:
an expected value data generation circuit that generates the expected value data based on an initial value in the write data training operation;
a first exclusive OR output circuit having one input terminal connected to the first latch circuit and the other input terminal connected to the expected value data generation circuit;
a first OR output circuit that receives an output signal of the first exclusive OR output circuit and the data indicating whether or not the bit error has occurred, and outputs a logical disjunction thereof; and
a third latch circuit that latches an output signal of the first OR output circuit, and outputs the latched signal as the data indicating whether or not the bit error has occurred.

7. The semiconductor memory device according to claim 6, further comprising:
a third pad electrode that receives the write data at the input of the write data to be written in the memory cell array and outputs the read data at the output of the read data read from the memory cell array;
a second comparator having one input terminal connected to the third pad electrode and the other input terminal to which the reference voltage is applied; and
a fourth latch circuit that latches an output signal of the second comparator corresponding to the first latch enable signal, wherein
the expected value generator/comparator further includes:
a second exclusive OR output circuit having one input terminal connected to the fourth latch circuit and the other input terminal connected to the expected value data generation circuit;
a second OR output circuit that receives an output signal of the second exclusive OR output circuit and data corresponding to the third pad electrode, and outputs a logical disjunction thereof; and
a fifth latch circuit that latches an output signal of the second OR output circuit, and outputs the latched signal as the data corresponding to the third pad electrode.

8. The semiconductor memory device according to claim 1, wherein
in the write data training operation,
address data that specifies expected value data is input,
the test data that matches the expected value data is input once or multiple times, and
respective bits of the expected value data are compared with respective bits of the input test data.

9. The semiconductor memory device according to claim 1, wherein
in the write data training operation,
the test data including a parity bit is input once or multiple times, and
the data indicating whether or not the bit error has occurred at the input of the test data is generated by performing a parity check.

10. The semiconductor memory device according to claim 9, further comprising:
a parallel conversion circuit that performs a serial-to-parallel conversion of the write data output from the first latch circuit, and outputs the converted data to the memory cell array via a data bus at the input of the write data;
a logic circuit that outputs “1” when a number of signals of “1” in respective bits of a signal of the data bus is an even number, and outputs “0” when the number of signals of “1” is an odd number;
a first OR output circuit that receives an output signal of the logic circuit and the data indicating whether or not the bit error has occurred, and outputs a logical disjunction thereof; and
a third latch circuit that latches an output signal of the first OR output circuit, and outputs the latched signal as the data indicating whether or not the bit error has occurred.

11. A memory system comprising:
a plurality of semiconductor memory devices; and
a controller connected to the plurality of semiconductor memory devices, wherein
each of the plurality of semiconductor memory devices include:
a memory cell array;
a first pad electrode that receives write data at an input of the write data to be written in the memory cell array and outputs read data at an output of the read data read from the memory cell array;
a first comparator having one input terminal connected to the first pad electrode and the other input terminal to which a reference voltage is applied;
a first latch circuit that latches an output signal of the first comparator corresponding to a first latch enable signal; and
a second pad electrode to which the first latch enable signal is supplied at the input of the write data, wherein
the semiconductor memory device is configured to be able to perform a write data training operation at an adjustment of a time interval between a timing of inputting the write data to the first pad electrode and a timing of inputting the first latch enable signal to the second pad electrode, and at an adjustment of the reference voltage,
in the write data training operation,
the controller inputs a plurality of bits of test data to the semiconductor memory device via the first pad electrode,
the semiconductor memory device generates data indicating whether or not a bit error has occurred at the input of the test data, and
the semiconductor memory device is configured to be able to output the data indicating whether or not the bit error has occurred.

12. The memory system according to claim 11, wherein
in the write data training operation,
the controller simultaneously inputs the plurality of bits of test data to the plurality of semiconductor memory devices, and
the controller causes the plurality of semiconductor memory devices to individually output the data indicating whether or not the bit error has occurred.
